(19) United States
(12) Patent Application Publication
(10) Pub. No.: US 2002/0090815 A1
(43) Pub. Date: Jul. 11, 2002

(54) Method for forming a deposited film by plasma chemical vapor deposition

(76) Inventors: Atsushi Koike, Kanagawa (JP); Masahiro Kanai, Tokyo (JP)

Correspondence Address: FITZPATRICK CELLA HARPER & SCINTO, 30 ROCKEFELLER PLAZA, NEW YORK, NY, 10112, US

(21) Appl. No.: 09/982,846

(22) Filed: Oct. 22, 2001

(30) Foreign Application Priority Data
Oct. 31, 2000 (JP) 2000-332383
Oct. 31, 2000 (JP) 2000-332382

(51) Int. Cl. H01L 21/44

(52) U.S. Cl. 438/680

(57) ABSTRACT

A film-forming method for forming a deposited film on a substrate arranged in a substantially enclosed film-forming vessel by means of plasma CVD by introducing a raw material gas comprising at least a hydrogen gas and a silicon-containing raw material gas into said film-forming vessel and introducing a high frequency power into said film-forming vessel through a discharge electrode provided in said film-forming vessel to generate a plasma in a plasma generation region between said substrate and said discharge electrode in said film-forming vessel whereby forming said deposited film on said substrate, wherein the formation of said deposited film on said substrate is performed while applying a periodicity voltage having at least two different waveform components having a different amplitude to an auxiliary electrode arranged at a position in said plasma generation region of said film-forming vessel or an auxiliary electrode provided on the rear side of said substrate and outside said plasma generation region.

### BACKGROUND OF THE INVENTION

1. Field of the Invention

The present invention relates to a method for forming a functional deposited film on a substrate by means of plasma chemical vapor deposition (hereinafter referred to simply as “plasma CVD”). More particularly, the present invention relates to a film-forming method by means of plasma CVD which enables one to efficiently form a high quality non-single crystal silicon series functional deposited film (such as a high quality amorphous silicon series functional deposited film or a high quality microcrystalline silicon series functional deposited film) having a homogeneous property over the entirety of a desired substrate having a large area at a high deposition rate, said deposited film being usable as a semiconductor element for semiconductor devices such as photovoltaic devices including solar cells, electrophotographic photosensitive devices (or electrophotographic light receiving members), image input line sensors, image pickup devices, and thin-film transistors in which amorphous silicon materials or amorphous alloy materials are used.

2. Related Background Art

It is known that an amorphous silicon film or a microcrystalline silicon film can be relatively easily formed by means of plasma CVD in comparison with the case of forming a crystalline silicon film or a polycrystalline silicon film. In this respect, an amorphous silicon film or a microcrystalline silicon film formed by means of plasma CVD has been frequently used in a semiconductor device required to have a large area such as a photovoltaic device (including a solar cell), an electrophotographic photosensitive device, an image input line sensor of a facsimile machine, or a thin-film transistor for a liquid crystal display.

Now, an amorphous or microcrystalline deposited film is generally formed by a film-forming method by means of plasma CVD (this method will be hereinafter referred to as “plasma CVD film-forming method”) wherein raw material gas is introduced into a deposition chamber in which a substrate is arranged and simultaneously with this, a high frequency power is introduced into said deposition chamber to decompose said raw material gas to produce a plasma in the vicinity of said substrate in said deposition chamber, whereby said deposited film is formed on said substrate arranged in said deposition chamber. In the case of forming an amorphous silicon deposited film having a large area on a desired substrate by the plasma CVD film-forming method, as the high frequency power, a high frequency power with an RF frequency (near 13.56 MHz) is used in many cases.

Incidentally, in recent years, there has been a demand for stably providing a large semiconductor device formed on a large area substrate. In order to comply with this demand, studies have been made of a large-sized plasma CVD apparatus which makes it possible to form a large area deposited film suitable for the production of such large semiconductor device. However, for such plasma CVD apparatus, there is a subject required to solve as will be described in the following. That is, for a deposited film having a small area formed by a plasma CVD apparatus which copes with a small film-forming area, the deposited film is acceptable in many cases even when it is ununiform in terms of the property. But it is difficult to stably and continuously form a large area deposited film which is satisfactory in terms of the uniformity of the property even when such large-sized plasma CVD apparatus is used.

Besides the above demand, there has been another demand for improving the film deposition rate along with the trend of using a large area substrate in view of improving the productivity. In order to meet this demand, there have been proposed several methods. Specifically, there have been proposed, for example, (1) a method of improving the film deposition rate by increasing the flow rate of film-forming raw material gas, and (2) a method of improving the film deposition rate by increasing the high frequency power for discharging to produce a plasma. Besides, (3) a plasma CVD method using a VHF (very high frequency) power with a frequency of about 30 MHz to 300 MHz has received attention as an useful technique in order to improve the film deposition rate. For instance, Amorphous Silicon Technology 1992 p. 15-26 (Material Research Society Symposium Proceedings Volume 258) discloses that by changing the discharging frequency from the frequency of RF with 13.56 GHz to a VHF, the film deposition rate can be markedly improved and a deposited film having a good property can be formed at a high speed.

The above-mentioned methods (1) to (3) are effective to improve the film deposition rate also upon forming a large area deposited film. However, any of these methods tends to entail a problem in the case of forming a large area deposited film in that the resulting large area deposited film is apparently inferior to a small area deposited film formed by the foregoing plasma CVD apparatus which copes with a small film-forming area in terms of the uniformity of the property distribution and also in terms of the property as a whole.

### SUMMARY OF THE INVENTION

The present invention has been accomplished in view of the foregoing situation of the prior art with respect to forming a large area deposited film.

The present invention makes it an object to provide a film-forming method by means of plasma CVD which enables one to efficiently and stably form a high quality non-single crystal silicon series deposited film including a high quality amorphous silicon series deposited film and a high quality microcrystalline silicon series deposited film having an excellent homogeneous property over the entirety of a large area at a high deposition rate.

The present inventors conducted studies through experiments in order to achieve the above object. As a result, there were obtained findings as will be described in the following. That is, it was found out that the cause of the foregoing problems relating to the film property in the prior art is due to (i) inappropriateness of the proportion between precursors (which contribute to forming a deposited film) which are generated from a film-forming raw material gas (excluding H₂ gas) and species generated from other raw material gas and (ii) inappropriateness of the ratio of the number of said precursors to that of hydrogen radicals generated. It was also found out that by adequately adjusting the proportion (i) and the ratio (ii), it is possible to prevent a large area deposited film formed on a given substrate having a large area at a high deposition rate from suffering unevenness of the property distribution over the entire surface of the substrate while preventing said deposited film from being deteriorated in terms of the property over the entire surface of the substrate.

The present invention has been accomplished on the basis of these findings.

Consequently, another object of the present invention is to provide a film-forming method for forming a deposited film on a substrate arranged in a substantially enclosed film-forming vessel by means of plasma CVD, comprising the steps of introducing at least hydrogen gas and silicon-containing raw material gas into said film-forming vessel and introducing a high frequency power into said film-forming vessel through a discharge electrode provided in said film-forming vessel to generate a plasma in a plasma generation region between said substrate and said discharge electrode whereby forming said deposited film on said substrate, characterized in that the formation of said deposited film on said substrate is performed while applying a periodicity voltage having at least two different waveform components having a different amplitude to an auxiliary electrode arranged in said plasma generation region of said film-forming vessel.

A further object of the present invention is to provide a film-forming method for forming a deposited film on a substrate arranged in a substantially enclosed film-forming vessel by means of plasma CVD, comprising the steps of introducing at least hydrogen gas and silicon-containing raw material gas into said film-forming vessel and introducing a high frequency power into said film-forming vessel through a discharge electrode provided in said film-forming vessel to generate a plasma in a plasma generation region between said substrate and said discharge electrode whereby forming said deposited film on said substrate, characterized in that said substrate is retained in a state of having a floating potential in said film-forming vessel, an auxiliary electrode is provided on a side opposite the film-forming face of said substrate in said film-forming vessel such that said auxiliary electrode is electrically isolated from said substrate, and the formation of said deposited film on said substrate is performed while applying a periodicity voltage having at least two different waveform components having a different amplitude to said auxiliary electrode.

According to the film-forming method of the present invention, it is possible to stably and efficiently form a high quality large area deposited film having a homogeneous property over the entire area thereof.

### BRIEF DESCRIPTION OF THE DRAWINGS

FIG. 1 is a schematic diagram illustrating the constitution of an example of a plasma CVD film-forming apparatus suitable for practicing the film-forming method of the present invention.

FIG. 2 shows a graph of examined results of emission intensities of hydrogen radical (H*) and those of SiH radical (SiH*) in relation to amplitudes of periodicity voltage applied to the auxiliary electrode in Example A1 which will be described later.

FIG. 3 shows a graph of examined results of emission intensities of hydrogen radical (H*) and those of SiH radical (SiH*) in relation to frequencies of a hydrogen radical-generating periodicity voltage applied to the auxiliary electrode in Example A1 which will be described later.

FIG. 4 shows a graph of examined results of emission intensities of hydrogen radical (H*) and those of SiH radical (SiH*) in relation to frequencies of a SiH radical-generating periodicity voltage applied to the auxiliary electrode in Example A1 which will be described later.

FIG. 5 is a graph schematically illustrating a waveform A of a periodicity voltage applied to the auxiliary electrode in Example A1 which will be described later.

FIG. 6 is a graph schematically illustrating a waveform B of a periodicity voltage applied to the auxiliary electrode in Example A1 which will be described later.

FIG. 7 is a graph schematically illustrating a waveform C of a periodicity voltage applied to the auxiliary electrode in Example A1 which will be described later.

FIG. 8 is a graph schematically illustrating a waveform D of a periodicity voltage applied to the auxiliary electrode in Example A1 which will be described later.

FIG. 9 shows a graph of examined results of emission intensities of hydrogen radical (H*) and those of SiH radical (SiH*) when a periodicity voltage having a waveform A, a periodicity voltage having a waveform B, a periodicity voltage having a waveform C, and a periodicity voltage having a waveform D were individually applied to the auxiliary electrode in Example A1 which will be described later.

FIG. 10 shows a graph of examined results of emission intensities of hydrogen radical (H*) and those of SiH radical (SiH*) when a periodicity voltage having a waveform A, a periodicity voltage having a waveform B, a periodicity voltage having a waveform C, and a periodicity voltage having a waveform D were individually applied to the auxiliary electrode in Example A2 which will be described later.

FIG. 11 is a schematic view illustrating installation positions of auxiliary electrodes upon examining a variation for photoelectric conversion efficiencies of photovoltaic elements in Example A3 which will be described later.

FIG. 12 is a graph schematically illustrating a waveform of a periodicity voltage applied to the auxiliary electrode in Example A3 which will be described later.

FIG. 13 is a graph schematically illustrating a waveform of a periodicity voltage applied to the auxiliary electrode in Example A4 which will be described later.

FIG. 14 is a schematic diagram illustrating the constitution of another example of a plasma CVD film-forming apparatus suitable for practicing the film-forming method of the present invention.

FIG. 15 shows a graph of examined results of emission intensities of hydrogen radical (H*) and those of SiH radical (SiH*) in relation to amplitudes of a periodicity voltage applied to the auxiliary electrode in Example B1 which will be described later.

FIG. 16 shows a graph of examined results of emission intensities of hydrogen radical (H*) and those of SiH radical (SiH*) in relation to frequencies of a hydrogen radical-generating periodicity voltage applied to the auxiliary electrode in Example B1 which will be described later.

FIG. 17 shows a graph of examined results of emission intensities of hydrogen radical (H*) and those of SiH radical (SiH*) in relation to frequencies of a SiH radical-generating periodicity voltage applied to the auxiliary electrode in Example B1 which will be described later.

FIG. 18 is a graph schematically illustrating a waveform A of a periodicity voltage applied to the auxiliary electrode in Example B1 which will be described later.

FIG. 19 is a graph schematically illustrating a waveform B of a periodicity voltage applied to the auxiliary electrode in Example B1 which will be described later.

FIG. 20 is a graph schematically illustrating a waveform C of a periodicity voltage applied to the auxiliary electrode in Example B1 which will be described later.

FIG. 21 is a graph schematically illustrating a waveform D of a periodicity voltage applied to the auxiliary electrode in Example B1 which will be described later.

FIG. 22 shows a graph of examined results of emission intensities of hydrogen radical (H*) and those of SiH radical (SiH*) when a periodicity voltage having a waveform A, a periodicity voltage having a waveform B, a periodicity voltage having a waveform C, and a periodicity voltage having a wave form D were individually applied to the auxiliary electrode in Example B1 which will be described later.

FIG. 23 shows a graph of examined results of emission intensities of hydrogen radical (H*) and those of SiH radical (SiH*) when a periodicity voltage having a waveform A, a periodicity voltage having a waveform B, a periodicity voltage having a waveform C, and a periodicity voltage having a wave form D were individually applied to the auxiliary electrode in Example B2 which will be described later.

FIG. 24 is a schematic view illustrating installation positions of auxiliary electrodes upon examining a variation for photoelectric conversion efficiencies of photovoltaic elements in Example B3 which will be described later.

FIG. 25 is a graph schematically illustrating a waveform of a periodicity voltage applied to the auxiliary electrode in Example B3 which will be described later.

FIG. 26 is a graph schematically illustrating a waveform of a periodicity voltage applied to the auxiliary electrode in Example B4 which will be described later.

### DESCRIPTION OF THE INVENTION AND PREFERRED EMBODIMENTS

The present invention includes the following two aspects.

A first aspect of the present invention provides a film-forming method for forming a deposited film on a substrate arranged in a substantially enclosed film-forming vessel by means of plasma CVD, said film-forming vessel being provided with a raw material gas introduction means and an exhaustion means, said film-forming method comprising the steps of introducing a raw material gas comprising at least a hydrogen gas and a silicon-containing raw material gas into said film-forming vessel through said raw material gas introduction means, maintaining an inner pressure of said film-forming vessel at a desired value by means of said exhaustion means and introducing a high frequency power into said film-forming vessel through a discharge electrode provided in said film-forming vessel to generate a plasma in a plasma generation region between said substrate and said discharge electrode in said film-forming vessel whereby forming said deposited film on said substrate maintained at a desired temperature, characterized in that the formation of said deposited film on said substrate is performed while applying a periodicity voltage having at least two different waveform components having a different amplitude to an auxiliary electrode arranged at a position in said plasma generation region of said film-forming vessel.

In the film-forming method of the first aspect of the present invention, it is preferred that the periodicity voltage has (i) a waveform component having an amplitude capable of generating mainly a radical of a silicon-containing compound and (ii) a waveform component having an amplitude capable of forming mainly a radical of hydrogen (hydrogen radical). Similarly, it is preferred that the discharge electrode is arranged such that it is opposed to a film-forming surface of the substrate and is situated at a position between the substrate and the discharge electrode.

The film-forming method of the first aspect of the present invention provides such significant advantages as will be described in the following. The film-forming method makes it possible to stably and efficiently form a high quality large area deposited film having a homogeneous property over the entire area thereof. Particularly, even when the substrate has a certain potential value, an electric field with an adequate intensity is generated in the plasma generated in the film-forming vessel to efficiently accelerate electrons contained in the plasma without causing ions having a high energy which influence adverse effects to the quality of a deposited film formed whereby efficiently generating desirable precursors and hydrogen radicals which contribute to forming a deposited film having a good property are efficiently produced, and as a result, a deposited film having an excellent homogeneous property is formed over the entirety of a large area.

A second aspect of the present invention provides a film-forming method for forming a deposited film on a substrate arranged in a substantially enclosed film-forming vessel by means of plasma CVD, said film-forming vessel being provided with a raw material gas introduction means and an exhaustion means, said film-forming method comprising the steps of introducing a raw material gas comprising at least a hydrogen gas and a silicon-containing raw material gas into said film-forming vessel through said raw material gas introduction means, maintaining an inner pressure of said film-forming vessel at a desired value by means of said exhaustion means, and introducing a high frequency power into said film-forming vessel through a discharge electrode provided in said film-forming vessel to generate a plasma in a plasma generation region between said substrate and said discharge electrode in said film-forming vessel whereby forming said deposited film on said substrate maintained at a desired temperature, characterized in that said substrate is retained in a state of having a floating potential in said film-forming vessel, an auxiliary electrode is provided on a side opposite a film-forming face of said substrate in said film-forming vessel such that said auxiliary electrode is electrically isolated from said substrate, and the formation of said deposited film on said substrate is performed while applying a periodicity voltage having at least two different waveform components having a different amplitude to said auxiliary electrode.

In the film-forming method of the second aspect of the present invention, it is preferred that the periodicity voltage has (i) a waveform component having an amplitude capable of generating mainly a radical of a silicon-containing compound and (ii) a waveform component having an amplitude capable of generating mainly a hydrogen radical. Similarly, it is preferred that the auxiliary electrode is arranged so that even when a conductive deposited is formed on the substrate, the conductive deposited film has a potential capable of being maintained at a floating potential.

The film-forming method of the second aspect of the present invention provides such significant advantages as will be described in the following. The film-forming method makes it possible to stably and efficiently form a high quality large area deposited film having a homogeneous property over the entire area thereof. Particularly, in the film-forming method of the second aspect of the present invention, the auxiliary electrode is provided at a position on the rear side of the substrate and outside the plasma generating region (the discharge region) of the film-forming vessel, and therefore, the auxiliary electrode never disturbs the plasma generated in the film-forming vessel. And even when any substrate made of a desired material is used as the substrate on which a deposited film is to be formed, it is possible to generate an electric field having a necessary intensity in the plasma generated in the film-forming vessel through the substrate, where said electric field generated in the plasma efficiently accelerates electrons contained in the plasma without causing ions having a high energy which influence adverse effects to the quality of a deposited film formed thereby to efficiently generate desirable precursors and hydrogen radicals which contribute to forming a deposited film having a good property, and as a result, a deposited film having an excellent homogeneous property is formed over the entirety of a large area.

In the following, detailed description will be made of the features and advantages of the present invention.

As being generally known in the technical field to which the present invention pertains, in the case where an electrode is arranged in a region where a plasma is generated and a prescribed voltage (a prescribed potential) is applied to the electrode situated in the plasma generated, when the voltage applied to the electrode is higher than the potential of the plasma (hereinafter simply referred to as “plasma potential”), an electron sheath is formed at the surface of the electrode, and an ion sheath is formed at the surface of the electrode when the voltage applied to the electrode is lower than the plasma potential.

In the case of the first aspect of the present invention, the auxiliary electrode which is provided in the plasma generation region (the discharge region) is corresponding to aforesaid electrode. In the case of the second aspect of the present invention, since the auxiliary electrode is provided on the rear side of the substrate and the substrate is positioned to expose the plasma generation region, the substrate is corresponding to aforesaid electrode.

Now, in the meaning of accelerating the electrons in the plasma, there is not found an apparent difference between an effect when a prescribed voltage is applied to the electrode so as to form an ion sheath thereon and that when a prescribed voltage is applied to the electrode so as to form an electron sheath thereon. However, in the case where the auxiliary electrode is provided in the plasma generation region of the film-forming vessel (the first aspect of the present invention), an apparent difference is occurred between an effect when a prescribed voltage is applied to the auxiliary electrode so that the electrons in the plasma are flown into the auxiliary electrode and that when a prescribed voltage is applied to the auxiliary electrode so that the electrons are not flown into the auxiliary electrode. That is, in the former case, the auxiliary electrode is significantly heated to entail a problem in that a deposited film formed on the substrate is inferior particularly in terms of the film property. On the other hand, in the latter case, such significant heating of the auxiliary electrode is not occurred, and there is formed a deposited film formed on the substrate which excels in the film property and the uniformity of the property distribution. This situation is similar also in the case where the auxiliary electrode is provided on the rear side of the substrate and outside the plasma generation region (the second aspect of the present invention). Particularly, under condition in that the electrons are flown into the electrode provided in the plasma generation region, the electrons get into the substrate which is exposed to the plasma generation region to significantly heat the substrate and as a result, a deposited film formed on the substrate becomes inferior particularly in terms of the film property.

In consequence, it is considered to be effective that a voltage which is lower than the plasma potential is applied to the auxiliary electrode.

In the present invention, such drawback as above described is effectively eliminated by way of application of a periodicity voltage such that the potential of the voltage once applied to the electrode (the auxiliary electrode or the substrate) is returned to a magnitude approximate to the plasma potential so that successive electrons reach in the vicinity of the electrode and thereafter, a voltage with a potential which is lower than the plasma potential is applied to the electrode. The electric field formed in this way accelerate the electrons in the plasma, whereby the raw material gas is efficiently dissociated to produce precursors (SiH*, SiH₂*, SiH₃*, H*, and the like) which contribute to forming a deposited film at a high yield.

In the present invention, for the periodicity voltage having at least two different waveform components having a different amplitude, the at least two different waveform components having a different amplitude (a voltage lapse between adjacent peaks imparting an amplitude in a voltage-time curve) are preferred to be set respectively such that an electric field having an optimum intensity is generated in the plasma so as to selectively generate a necessary precursor. And the periodicity voltage is preferred to be applied to the auxiliary electrode in a direction where no electron is flown into the auxiliary electrode. In general, the amplitude potential is preferred to be made such that radicals such as H* from hydrogen (which is an essential precursor in the ordinary CVD) and SiH* and the like from a silane (such as SiH₄) are selectively generated. The generation ratio of such radicals can be controlled depending on the number of voltage application repetitive cycles per an unite time.

In the present invention, the periodic change in the electric field which is caused by the application of the periodicity voltage is performed in order to prevent the ion sheath from being formed at the auxiliary electrode. As the power source for the voltage, a high frequency power with a frequency which substantially does not impart an electric field effect to the ions is preferably used. By this, it is possible to perform continuous and effective acceleration of the electrons in that the electrons in the vicinity of the electric field application mechanism are sprung out and they are returned in the vicinity of the electric field application mechanism for every cycle of the application of the periodicity voltage having at least two different waveforms having a different amplitude, where substantially no kinetic energy is imparted to the ions (the plasma potential is substantially not changed in other words).

Further, in the present invention, the electric field is formed in the plasma already generated for the formation of a deposited film. This situation makes it possible to accelerate the electrons in the plasma to have an energy capable of effectively dissociating and activating the raw material gas (for the formation of a deposited film) by means of an electric field with a minimum intensity without going through a dissociation process of the raw material gas. The point where the dissociation process of the raw material gas is not experienced is an important feature of the present invention. That is, because of not including the dissociation process, the quantity of a current flown into the electrode (the auxiliary electrode) is sufficient to be extremely small, and as a result, the electrode is heated to a very small extent upon film formation.

This situation provides pronounced advantages as will be described in the following also in the first aspect of the present invention where the auxiliary electrode is provided in the plasma generation region of the film-forming vessel. That is, the auxiliary electrode can be shaped in a simple and appropriate form in thermal and electrical viewpoints. And even when an auxiliary electrode shaped in such appropriate form is arranged in the vicinity of the substrate, a deposited film formed on the substrate hardly receives an influence of the auxiliary electrode in terms of the physical properties and the configuration.

In the second aspect of the present invention where the auxiliary electrode is provided on the rear side of the substrate and outside the plasma generation region of the film-forming vessel, it is also an important feature that the auxiliary electrode which forms an electric field by which the electrons are accelerated is not situated in the plasma generated for the formation of a deposited film. This situation provides pronounces as will be described in the following. That is, substantially no stagnation is occurred in the gas flow in the plasma and the plasma receives no foreign matter from the auxiliary if it should be occurred, and therefore, the auxiliary electrode has no adverse influence to the property and the property distribution of a deposited film formed on the substrate. In addition, even when the distance between the discharge electrode (the main electrode) and the substrate is extremely small, it is possible to efficiently generate a desirable electric field in the plasma without any problem. Further, because the auxiliary electrode is provided not in but outside the plasma generation region, there is more freedom for the shape and configuration of the auxiliary electrode in comparison with the auxiliary electrode used in the first aspect of the present invention. For instance, it is possible to arrange a desired electrode as the auxiliary electrode in a tiny space between the substrate heating mechanism and the substrate. Specifically, for example, an electrode comprising a thin plate made of a dielectric material such as quartz and an electrode pattern of a metal thin film formed on said thin plate or an electrode comprising a plurality of metallic wires as the auxiliary substrate can be arranged in said space.

Further in addition, in the second aspect of the present invention, the substrate is retained in a state of having a floating potential (an unearthed state) in the film-forming vessel. Because of this, even when a conductive deposited film is formed on the substrate, by making such that the potential of the conductive film is maintained at a floating potential, it is possible that the electric field formed by the auxiliary electrode is prevented from being extinguished in the film by way of the electrostatic screening of the conductive film and a desirable electric field sufficient to accelerate the electrons is formed on the surface of the substrate even when the surface of the substrate is completely covered by the conductive film.

Incidentally, so far, for instance, as described in Japanese Unexamined Patent Publication No. Hei.5 (1993)-24992, Japanese Patent Publication No. 2819030, and Japanese Patent Publication No. 2819031, the energy of an ion has been controlled by means of a steady electric field (an electric field of direct current which is substantially not changed) generated by applying a given electric power or potential to a given electrode which is arranged in the plasma generation region in many cases. However, as the electron-accelerating means for accelerating (highly energizing) an electron in order to generate a specific precursor (for example, a specific radical, etc.) for forming a deposited film, there has not proposed a method of applying a periodic electric field as in the present invention. Particularly, the present invention includes a method wherein a specific precursor (including a hydrogen radical) capable of contributing to forming a deposited film is efficiently and selectively generated by imparting a specific energy to only an electron by means of a high frequency electric field to which no ion can follow (which does not impart an energy to an ion). This method cannot be found in or easily expected from the prior art. Besides, as in the second aspect of the present invention, the present invention include a method wherein as the electron-accelerating means for accelerating the electron in order to generate a specific precursor, the auxiliary electrode is provided on the rear side of the substrate and outside the plasma generation region. This method also cannot be found or easily expected from the prior art.

In the following, preferred embodiments of the present invention will be described. [High frequency power applied to the discharge electrode]

The discharge electrode used in the present invention (the first aspect and the second aspect of the present invention) plays the following two roles.

A first role is to perform generation of a principal precursor, which is capable of being generated with an energy of less than an electron temperature in ordinary plasma generated for the formation of a deposited film, within a range where the concentration of an unnecessary active species in the plasma which is generated concurrently with said precursor is allowable with respect to the property of a deposited film formed.

A second role is to generate an electron essential upon generating a principal precursor in a supplementary amount by the auxiliary electrode.

In order for the discharge electrode to play these roles, a discharge-generating high frequency power with a prescribed frequency capable of efficiently decomposing the raw material gas to generate a plasma uniformly over the entirety of a large area is applied to the discharge electrode. Such frequency is preferably in a range of from 10 kHz to 1 GHz or more preferably in a range of from 1 MHz to 200 MHz, respectively belonging a high frequency band region which is differentiated from and lower than a microwave band region which is generally called so in the technical field to which the present invention pertains.

When the frequency is smaller than about 10 kHz, there is a tendency in that the decomposition efficiency of the raw material gas is diminished. When the frequency is beyond about 1 GHz, there is a tendency in that to generate a plasma over the entirety of a large area becomes to be difficult.

[Substrate and Retaining State Thereof]

As the substrate on which a deposited film is to be formed in the present invention, any known substrates which are used for forming silicon-containing films such as amorphous silicon films, microcrystalline silicon films, and other crystalline silicon films may be optionally used, regardless of whether they are conductive, semiconductive, or insulative. For the configuration of the substrate, any configuration may be adopted as long as the configuration of the discharge electrode and that of the auxiliary electrode are optimized to agree with the configuration of the substrate.

In the first aspect of the present invention, the substrate is retained in the film-forming vessel while being electrically grounded, that is, the substrate is retained in an earthed state in the film-forming vessel. However, it is possible to retain the substrate in a state of having a floating potential (an unearthed state) in the film-forming vessel depending upon the situation involved.

In the second aspect of the present invention, the substrate is preferred to be retained in a state of having a floating potential (an unearthed state) in the film-forming vessel. By retaining the substrate in this way, even when a conductive deposited film is formed on the substrate, the potential of the conductive film is maintained at a floating potential. Because of this, it is possible that the electric field formed by the auxiliary electrode is prevented from being extinguished in the film by way of the electrostatic screening of the conductive film and a desirable electric field sufficient to accelerate the electrons in the plasma is formed on the surface of the substrate even when the surface of the substrate is completely covered by the conductive film.

[Auxiliary electrode]

The auxiliary electrode used in the present invention may be shaped in an appropriate form such as a round bar form, a square bar form, a plate form, or a mesh form. In any case, the auxiliary electrode is preferred to be configured so that the field intensity can be prevented from being localized on the surface thereof as much as possible. For this purpose, the auxiliary electrode is preferred to be configured such that it has no edge and the tip portion is not opposed to the film-forming face of the substrate.

For the auxiliary electrode used in the first aspect of the present invention where the auxiliary electrode is provided in the plasma generation region of the film-forming vessel, it is preferred to comprise an electrode made of a conductive material having a high physical strength such as a metallic material and which is shaped in a round bar form or a form similar to said form, which is miniaturized to a possible extent so as to have neither an edge nor a tip portion which is opposed to the film-forming face of the substrate.

For the optimum electrode length of the auxiliary electrode in the film-forming method of the first aspect, it should be properly determined depending on the arrangement thereof in the plasma generation region between the substrate and the discharge electrode. In the case where the raw material gas is flown in parallel to the substrate and in one direction in the plasma generation region, the electrode length of the auxiliary electrode is preferred to be designed such that it is substantially the same as the width of the substrate which is perpendicular to the direction of the raw material gas flow or it is somewhat longer than said width of the substrate. The reason for this is that when the auxiliary electrode is arranged so as to be in parallel to the substrate (that is, the film-forming face of the substrate) and to be perpendicular to the direction of the raw material gas flow, the precursors including hydrogen radicals (which contribute to forming a deposited film) which are generated in the vicinity of the auxiliary electrode are made to be uniformly supplied to the entirety of a surface of the substrate which is situated in a downstream side of the location of the auxiliary electrode with respect to the direction of the raw material gas flow.

To retain the auxiliary electrode in the plasma generation region may be conducted, for example, by a manner of penetrating one or opposite end portions of the auxiliary electrode the wall (which is electrically earthed) of the film-forming vessel and hermetically fixing the end portion(s) of the auxiliary electrode with the wall of the film-forming vessel with an insulating material such as ceramics so that the end portion(s) of the auxiliary electrode is electrically isolated from the wall of the film-forming vessel.

In the film-forming method of the first aspect of the present invention, the number of the auxiliary electrode arranged in the plasma generation region of the film-forming vessel is not limited to one. It is possible that a plurality of auxiliary electrodes having such configuration as above described are spacedly arranged in the plasma generation region of the film-forming vessel.

For the auxiliary electrode used in the film-forming method of the second aspect of the present invention where the auxiliary electrode is provided on the rear side and outside the plasma generation region, it may comprise an electrode comprising a thin plate made of a dielectric material such as quartz and an electrode pattern of a metal thin film formed on said thin plate or an electrode comprising a plurality of metallic wires as previously described. Besides, it is possible to use a metal plate as it is as the auxiliary electrode used in the second aspect of the present invention.

For the optimum electrode length of the auxiliary electrode in the film-forming method of the second aspect of the present invention, it should be properly determined depending on the situation of how the auxiliary electrode is installed on the rear side of the substrate. In the case where the raw material gas is flown in parallel to the substrate and in one direction in the plasma generation region, the electrode length of the auxiliary electrode is preferred to be designed such that it is substantially the same as the width of the substrate which is perpendicular to the direction of the raw material gas flow or it is somewhat longer than said width of the substrate. The reason for this is that when the auxiliary electrode is arranged on the rear side of the substrate such that it is in parallel to the substrate and is perpendicular to the direction of the raw material gas flow, the precursors including hydrogen radicals (which contribute to forming a deposited film) which are generated in the vicinity of the substrate are made to be uniformly supplied to the entirety of a surface of the substrate which is situated in a downstream side of the location of the auxiliary electrode with respect to the direction of the raw material gas flow.

To retain the auxiliary electrode on the rear side of the substrate may be conducted, for example, by a manner of penetrating one or opposite end portions of the auxiliary electrode the wall (which is electrically earthed) of the substrate holder and hermetically fixing the end portion(s) of the auxiliary electrode with the wall of the substrate holder with an insulating material such as ceramics so that the end portion(s) of the auxiliary electrode is electrically isolated from the wall of the substrate holder.

In the film-forming method of the second aspect of the present invention, the number of the auxiliary electrode arranged on the rear side of the substrate is not limited to one. It is possible that a plurality of auxiliary electrodes having such configuration as above described are spacedly arranged on the rear side of the substrate.

[Voltage Whose Voltage Waveform is Periodically Changed, Applied to the Auxiliary Voltage]

In the present invention (the first aspect and the second aspect of the present invention), a high frequency voltage whose voltage waveform is periodically changed is applied to the auxiliary voltage upon forming a deposited film on the substrate.

In the present invention (the first aspect and the second aspect of the present invention), it is required to accelerate the electrons in the plasma during the time when the potential of the auxiliary electrode is changed from a potential approximate to the plasma potential to a prescribed lower potential (a potential having a negative polarity and which is in a direction where the absolute value is increased). In consequence, for the voltage waveform (which is periodically changed) of the high frequency voltage applied to the auxiliary electrode, it is preferred to be a voltage waveform whose building-up is sharp. In this respect, a rectangular waveform and a trapezoidal waveform are suitable as the voltage waveform.

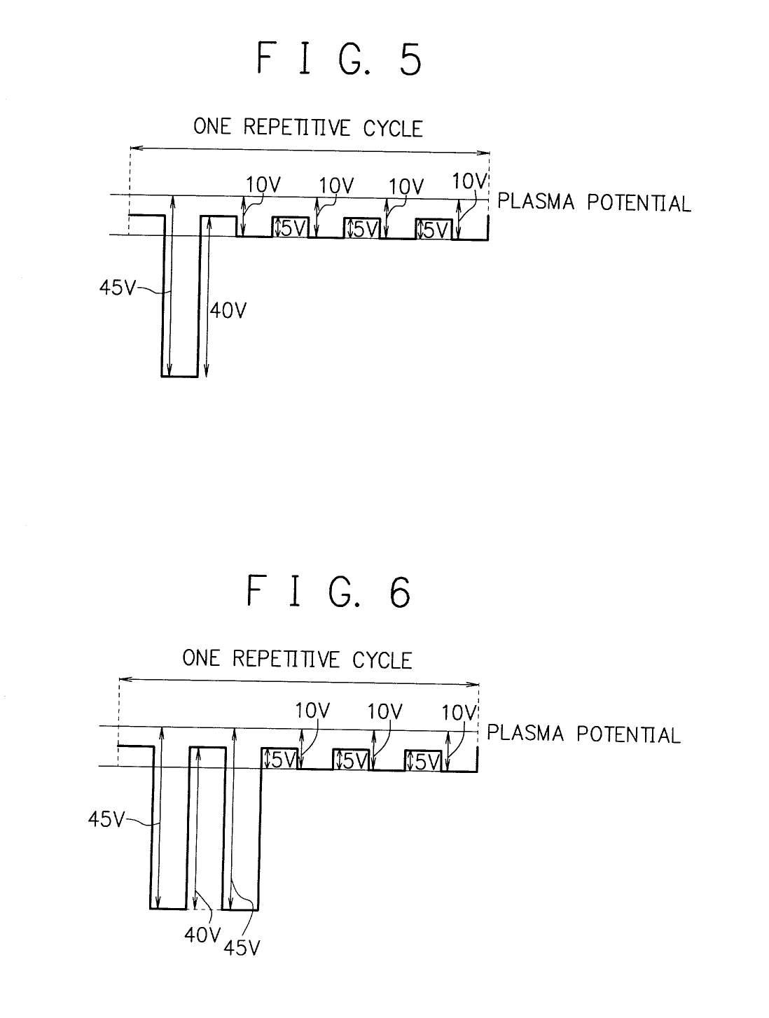

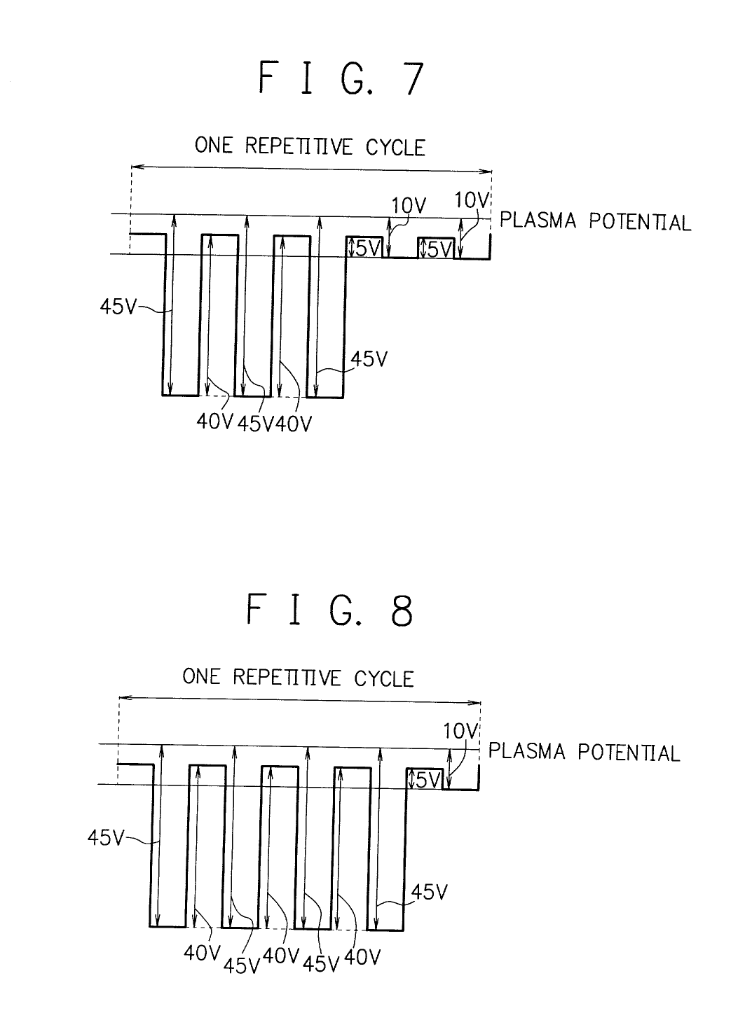

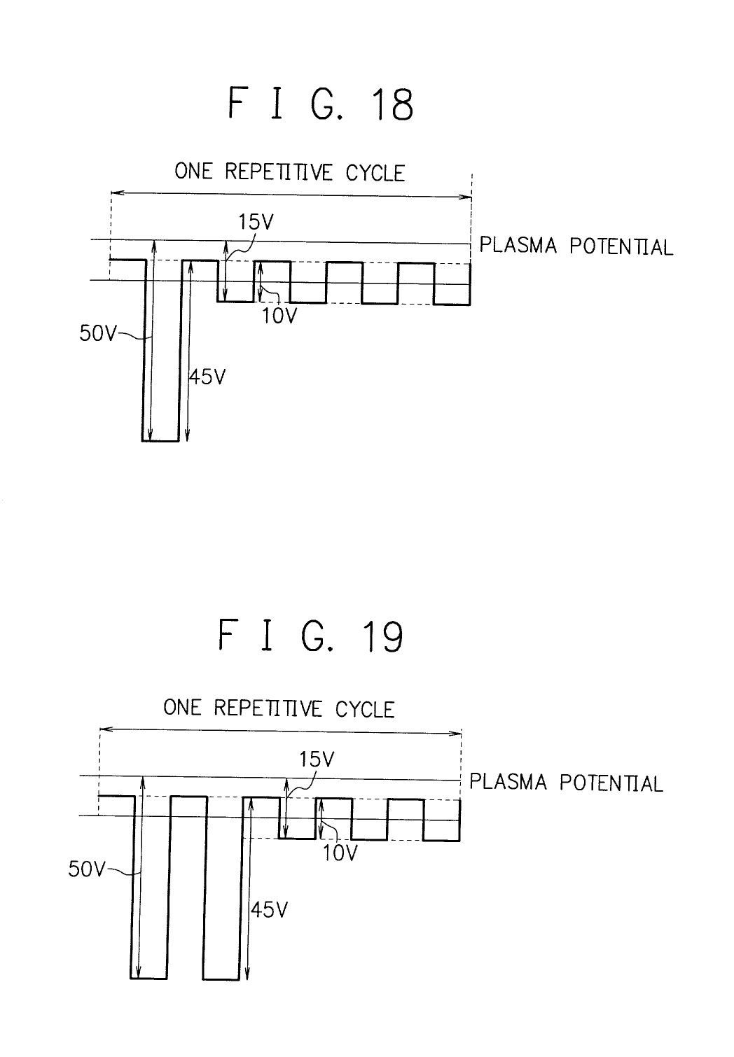

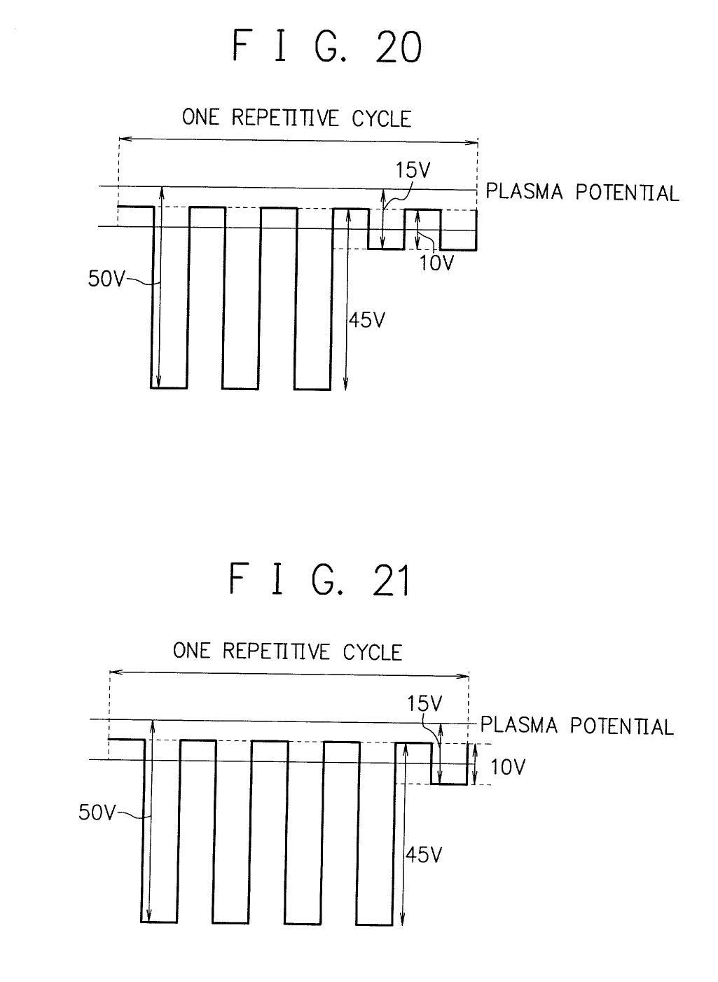

Specific examples of the rectangular waveform are shown in FIGS. 5 to 8 (which are used in the first aspect of the present invention) and also in FIGS. 18 to 21 (which are used in the second aspect of the present invention). When it is intended to accelerate the electrons in the plasma to collide with the raw material gas whereby generating radicals of the raw material gas, this object can be achieved by arranging an appropriate electrode (as the auxiliary electrode) in the plasma generation region and applying a high frequency voltage of any of the foregoing waveforms to the electrode. In this case, when it is intended to impart an energy of a prescribed electron volt (eVa) to the electrons, this object can be achieved by applying the high frequency voltage at a prescribed amplitude (Va) which is differentiated from the plasma potential (Vp). The following of the electrons against the electric field generated at the time of the application of the high frequency voltage is good enough, where the frequency of the following is more than several tens GHz. When any of the waveforms shown in the foregoing figures is used, SiHx radicals are generated at 5 eV and H radicals are generated at 40 eV.

Now, the reason why the voltage is not applied constantly at a fixed value in a direct current manner is that in the case where a voltage which is lower than the plasma potential is applied, in order to continuously accelerate the electrons without having intermission, it is necessitated to establish a weak electric field application time during which after the electrons in the vicinity of the auxiliary electrode are sprung out therefrom, they are returned there (specifically, for instance, a time during which a value which is lower by 5 V than the plasma potential is taken, as shown in FIG. 5). When this weak electric field application time is established, the electrons are not returned in the vicinity of the auxiliary electrode and as a result, to impart the energy to the electrons is terminated and the generation of the radicals is also terminated.

For the frequency of the high frequency voltage applied to the auxiliary electrode, the lower limit thereof is made to be preferably 100 kHz or more or more preferably 1 MHz or more in order that unnecessary acceleration (high energization) of the ions in the plasma is not induced, and the upper limit thereof is made to be preferably 500 MHz or less or more preferably 100 MHz or less in order that uniformity of the electrode surface potential is ensured.

There is no particular limitation for the maximum amplitude of the high frequency voltage applied to the auxiliary. However, in order that ionization of hydrogen is not induced, it is effective under various conditions that the maximum amplitude of the high frequency voltage applied to the auxiliary is made to be less than about 80 V which is corresponding to the maximum ionization cross-section of hydrogen molecule. Taking into account that the maximum dissociation cross-section of hydrogen molecule is about 16 eV and also taking penetration of the electric field into the plasma and the extent of attenuation of the electric field into consideration, the maximum amplitude of the high frequency voltage applied to the auxiliary is made to be preferably in a range of from 5 V to 80 V or more preferably in a range of from 5 V to 60 V.

[Raw Material Gas]

As the raw material gas used in the present invention in order to form a silicon-containing deposited film (hereinafter referred to as “silicon deposited film”), specifically, a non-single crystal silicon deposited film such as an amorphous silicon (a-Si) deposited film or a microcrystalline silicon deposited film, basically, a raw material gas capable of supplying silicon atoms (Si) upon film formation and hydrogen gas (H₂) are together used. In the case of using a raw material gas capable of supplying silicon atoms (Si) and hydrogen atoms (H) upon film formation, it is not always necessary to use hydrogen gas (H₂).

In the present invention, it is possible to form a non-single crystal silicon deposited film containing silicon atoms as a matrix and other atoms such as germanium atoms (Ge), carbon atoms (C), and the like (this non-single deposited film will be hereinafter referred to as “non-single crystal silicon series deposited film”).

In order to form such non-single silicon series deposited film, for instance, a raw material case capable of supplying germanium atoms (Ge) or carbon atoms (C) upon film formation is used in addition to the raw material gas capable of supplying silicon atoms and hydrogen atoms.

Further, in the present invention, it is possible to form a non-single crystal silicon deposited film or a non-single crystal silicon series deposited film whose conductivity is controlled to p-type or n-type.

In order to form such p-type or n-type deposited film, a raw material gas capable of supplying atoms of a given conductivity controlling element is introduced into the film-forming vessel upon forming a non-single crystal silicon deposited film or a non-single crystal silicon series deposited film.

The Si-supplying raw material gas can include gaseous or easily gasifiable chain silane compounds and cyclic silane compounds. Specific examples are SiH₄, Si₂H₆, SiFH₃, SiF₂H₂, SiF₃H, Si₃H₈, SiD₄, SiHD₃, SiH₂D₂, SiH₃D, SiF₂D₂, Si₂D₃H₃, SiH₂F₄, Si₂H₃F₃, SiHCl₃, SiH₂Br₂, and SiH₂Cl₂, wherein D indicates heavy hydrogen. These silane compounds are capable of supplying silicon atoms (Si) and hydrogen atoms upon film formation. Therefore, it is always necessary to additionally use hydrogen gas (H₂).

Besides the above-mentioned silane compounds, SiF₄, Si₂F₆, Si₃F₈, (SiF₂)₄, (SiF₂)₅, (SiF₂)₆, SiCl₄, Si₂Cl₆, (SiCl₂)₅, Si₂Cl₃F₃, SiBr₄, and (SiBr₂)₅ are usable as the Si-supplying raw material. However, since these silane compounds are not capable of supplying hydrogen atoms together with silicon atoms, in the case of using only these silane compounds as the Si-supplying raw material gas, it is necessary to use hydrogen gas (H₂).

The above-mentioned silane compounds may be used either singly or in combination of two or more of them.

Separately, it is possible that any of the above-mentioned silane compounds is introduced into the film-forming vessel by diluting with a dilution gas such as H₂ gas, He gas, Ne gas, Ar gas, Xe gas, or Kr gas.

The Ge-supplying raw material gas can include gaseous or easily gasifiable germanium-containing compounds such as GeH₄, Ge₂H₆, GeHD₃, GeH₂D₂, Ge₂H₃D₃, GeD₄, Ge₂D₆, GeF₄, GeHF₃, GeF₃H, and GeF₂H₂. These germanium-containing compounds may be used either singly or in combination of two or more of them. It is possible that these germanium-containing compounds are introduced into the film-forming vessel by diluting with a dilution gas such as H₂ gas, He gas, Ne gas, Ar gas, Xe gas, or Kr gas.

The C-supplying raw material gas can include gaseous or easily gasifiable carbon-containing compounds such as CH₄, CD₄, CₙH₂ₙ₊₂ (with n being an integer), C₂H₂, CO₂, and CO. These carbon-containing compounds may be used either singly or in combination of two or more of them. It is possible that these carbon-containing compounds are introduced into the film-forming vessel by diluting with a dilution gas such as H₂ gas, He gas, Ne gas, Ar gas, Xe gas, or Kr gas.

For the raw material gas capable of supplying atoms of a given conductivity controlling element, the conductivity controlling element can include so-called impurities in the semiconductor field, specifically, elements belonging to group IIIb of the periodic table which provide a p-type conductivity (hereinafter simply referred to as group IIIb element) and elements belonging to group Vb of the periodic table which provide an n-type conductivity (hereinafter simply referred to as group Vb element).

Specific examples of the group IIIb element are B, Al, Ga, In and Tl. Specific examples of the group Vb element are P, As, Sb and Bi.

The raw material gas capable of supplying atoms of the group IIIb element can include gaseous or easily gasifiable boron hydrides such as B₂H₆, B₄H₁₀, B₅H₁₁, B₆H₁₀, B₆H₁₂, and B₆H₁₄, and gaseous or easily gasifiable boron halides such as BF₃, and BCl₃. Besides, gaseous or easily gasifiable AlC₃, GaCl₃, InCl₃, and TlCl₃ are also usable. Of these, B₂H₆ and BF₃ are particularly suitable.

The raw material gas capable of supplying atoms of the group Vb element can include gaseous or easily gasifiable phosphorous hydrides such as PH₃, and P₂H₄ and gaseous or easily gasifiable phosphorous halides such as PF₃, PF₅, PCl₃, PCl₅, PBr₃, PBr₅, and PI₃. Besides, gaseous or easily gasifiable AsH₃, AsF₃, AsF₅, AsCl₃, AsBr₃, SbH₃, SbF₃, SbF₅, SbCl₃, SbCl₅, BiH₃, BiCl₃, and BiBr₃ are also usable. Of these, PH₃ and PF₃ are particularly suitable.

Any of the conductivity controlling atoms-supplying compounds may be diluted with a dilution gas such as H₂ gas, He gas, Ne gas, Ar gas, Xe gas, or Kr gas, upon the introduction thereof into the film-forming vessel.

[Film-forming Apparatus]

FIG. 1 is a schematic diagram illustrating the constitution of an example of a plasma CVD film-forming apparatus suitable for practicing the film-forming method of the first aspect of the present invention.

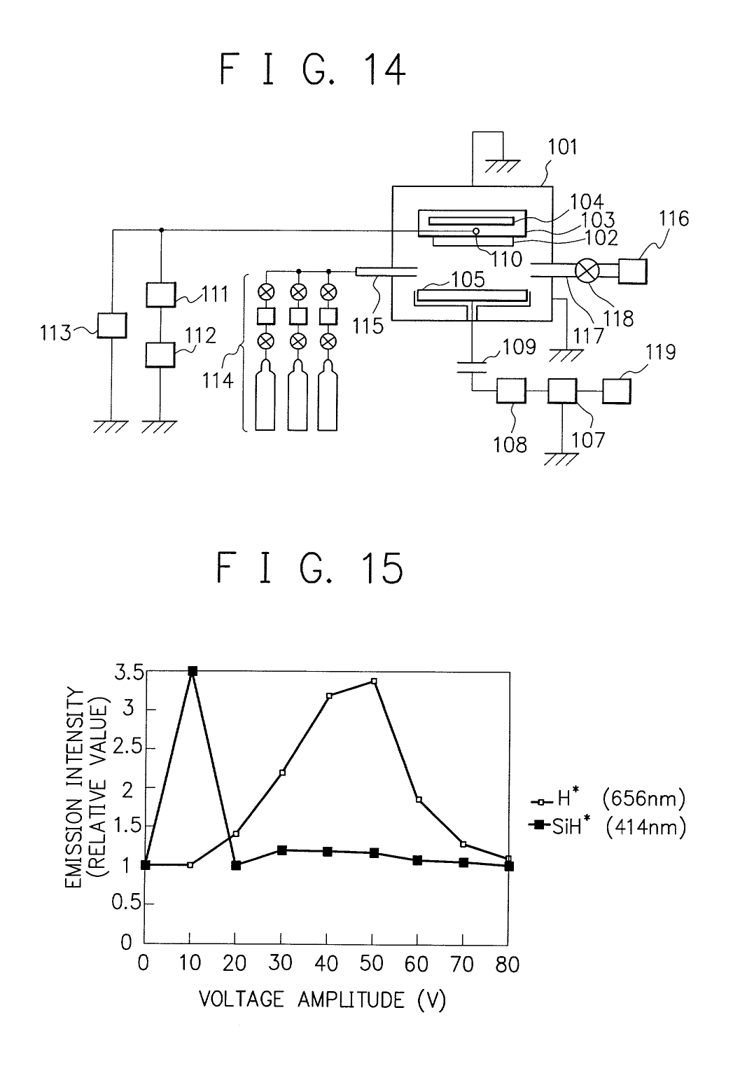

FIG. 14 is a schematic diagram illustrating the constitution of an example of a plasma CVD film-forming apparatus suitable for practicing the film-forming method of the second aspect of the present invention.

In the following, description will be made of the film-forming apparatus shown in FIG. 1.

The film-forming apparatus shown in FIG. 1 has a film-forming vessel 101 whose inside is capable of being evacuated and which is structured such that in the film-forming chamber, an auxiliary electrode 110 shaped in a bar form is provided between a conductive substrate 102 and a discharge electrode 105 shaped in a plate form which is opposed to the substrate 102, and a periodicity voltage having at least two different waveform components having a different amplitude (a voltage lapse between adjacent peaks imparting an amplitude in a voltage-time curve) is applied to the auxiliary voltage 110. In FIG. 1, there is shown only one auxiliary electrode. This is not limitative. It is possible to use a plurality of auxiliary electrodes.

Particularly, as shown in FIG. 1, in the inside of the film-forming vessel 101, the conductive substrate 102 is held on a substrate holder 103, and the conductive substrate 102 is electrically earthed together with the film-forming vessel 101. Reference numeral 104 indicates a heater 104 which is provided in the substrate holder 103. The substrate 102 can be heated to and maintained at a prescribed temperature by means of the heater 104 upon film formation. The discharge electrode 105 is provided at a position to oppose the substrate 102 in the film-forming vessel 101. Reference numeral 106 indicates a cathode electrode which is provided at the discharge electrode 105. Reference numeral 107 indicates a high frequency power source which is connected to the discharge electrode 105 through a matching circuit 108 and a block condenser 109. Reference numeral 119 indicates a high frequency signal generator which is connected to the high frequency power source 107. Reference numeral 111 indicates a power amplifier [comprising a high speed power amplifier 4055 (produced by NF CIRCUIT DESIGN BLOCK Company)] which is connected to the auxiliary electrode 110. Reference numeral 112 indicates a high frequency signal generator [comprising a multifunction synthesizer wave factory 1952 (produced by NF CIRCUIT DESIGN BLOCK Company)] which is connected to the power amplifier 111. Reference numeral 113 indicates an oscilloscope which is connected to the auxiliary electrode 110. The oscilloscope 113 is used for measuring a surface potential of the auxiliary electrode 110. The film-forming vessel 101 is provided with a raw material gas introduction pipe 115 which is extending from a raw material gas supply system 114 comprising a plurality of reservoirs each containing a desired raw material gas therein. The film-forming vessel 101 is also provided with an exhaust pipe 117 which is connected to an exhaustion device 116 comprising a vacuum pump. Reference numeral 118 indicates a throttle valve which is provided at the exhaust pipe 117.

The film-forming method using the film-forming apparatus shown in FIG. 1 is performed, for example, as will be described below.

A prescribed substrate 102 is fixed onto the substrate holder 103 such that the substrate is in an electrically earthed state. The inside of the film-forming vessel 101 is evacuated to a prescribed vacuum through the exhaust pipe 117 by actuating the exhaustion device 116. While continuing the evacuation, He gas from the raw material gas supply system 114 is introduced into the film-forming vessel 101 through the raw material gas introduction pipe 115, where the inner pressure (the gas pressure) of the film-forming vessel 101 is maintained at a prescribed value by regulating the opening of the throttle valve 118. Then, the substrate 102 is heated to and maintained at a prescribed temperature by actuating the heater 104 provided in the substrate holder 103. Thereafter, the introduction of the He gas into the film-forming vessel 101 is terminated and simultaneously with this, for instance, SiH₄ gas and H₂ gas from the raw material gas supply system 114 are together introduced into the film-forming vessel 101 at prescribed respective flow rates through the raw material gas introduction pipe 115, and the inner pressure (the gas pressure) of the film-forming vessel 101 is adjusted to and maintained at a prescribed value by regulating the opening of the throttle valve 118. To the discharge electrode 105 (which is opposed to the substrate 102 while having a prescribed interval between the discharge electrode and the substrate), a high frequency power (with a prescribed frequency) of a prescribed wattage from the high frequency power source 107 is applied through the matching circuit 108 and the block condenser 109. At the same time, to the auxiliary electrode 110 (which is preferably arranged at a central position of a line formed by connecting the center of the substrate 102 and the discharge electrode 105 such that it is in parallel to the substrate and the discharge electrode and approximately perpendicular to the gas flow), a prescribed periodicity voltage having at least two different waveform components having a different amplitude is applied by means of the power amplifier 111 and the high frequency signal generator 112. By this, glow discharge is generated to produce a plasma in the presence of the raw material gas in the space between the substrate and the discharge electrode of the film-forming chamber, whereby the raw material gas is decomposed to form a non-single crystal silicon deposited film on the substrate 102.

As previously described, FIG. 14 is a schematic diagram illustrating the constitution of an example of a plasma CVD film-forming apparatus suitable for practicing the film-forming method of the second aspect of the present invention.

In the following, description will be made of the film-forming apparatus shown in FIG. 14.

The film-forming apparatus shown in FIG. 14 has a film-forming vessel 101 whose inside is capable of being evacuated and which is structured such that in the inside of the film-forming vessel 101, a substrate 102 is held on a substrate holder 103 designed to have a floating potential such that even when a conductive deposited film is formed on the substrate 102, the conductive deposited film can be maintained at a floating potential; on the rear side of the substrate 102 (that is, on the side of the non-film forming face of the substrate 102), an auxiliary electrode 110 shaped in a bar form is arranged in a state electrically isolated from the substrate 102; and a periodicity voltage having at least two different waveform components having a different amplitude (a voltage lapse between adjacent peaks imparting an amplitude in a voltage-time curve) is applied to the auxiliary voltage 110. In FIG. 14, there is shown only one auxiliary electrode. This is not limitaive. It is possible to use a plurality of auxiliary electrodes.

Particularly, as shown in FIG. 14, the film-forming vessel 101 is electrically earthed. A heater 104 is provided in the substrate holder 103 so that the substrate 102 held on the substrate holder 103 can be heated to and maintained at a prescribed temperature by means of the heater 104 upon film formation. The auxiliary electrode 110 is arranged between the heater 104 and the substrate 102. Reference numeral 105 indicates a discharge electrode shaped in a plate form which is provided at a position to oppose the substrate 102 in the film-forming chamber 101. Reference numeral 106 indicates a cathode electrode which is provided at the discharge electrode 105. Reference numeral 107 indicates a high frequency power source which is connected to the discharge electrode 105 through a matching circuit 108 and a block condenser 109. Reference numeral 119 indicates a high frequency signal generator which is connected to the high frequency power source 107. Reference numeral 111 indicates a power amplifier [comprising a high speed power amplifier 4055 (produced by NF CIRCUIT DESIGN BLOCK Company)] which is connected to the auxiliary electrode 110. Reference numeral 112 indicates a high frequency signal generator [comprising a multifunction synthesizer wave factory 1952 (produced by NF CIRCUIT DESIGN BLOCK Company)] which is connected to the power amplifier 111. Reference numeral 113 indicates an oscilloscope which is connected to the auxiliary electrode 110. The oscilloscope 113 is used for measuring a surface potential of the auxiliary electrode 110. The film-forming vessel 101 is provided with a raw material gas introduction pipe 115 which is extending from a raw material gas supply system 114 comprising a plurality of reservoirs each containing a desired raw material gas therein. The film-forming vessel 101 is also provided with an exhaust pipe 117 which is connected to an exhaustion device 116 comprising a vacuum pump. Reference numeral 118 indicates a throttle valve which is provided at the exhaust pipe 117.

The film-forming method using the film-forming apparatus shown in FIG. 14 is performed, for example, as will be described below.

A prescribed substrate 102 is fixed onto the substrate holder 103 such that the substrate is in a state of having a floating potential. The inside of the film-forming vessel 101 is evacuated to a prescribed vacuum through the exhaust pipe 117 by actuating the exhaustion device 116. While continuing the evacuation, He gas from the raw material gas supply system 114 is introduced into the film-forming vessel 101 through the raw material gas introduction pipe 115, where the inner pressure (the gas pressure) of the film-forming vessel 101 is maintained at a prescribed value by regulating the opening of the throttle valve 118. Then, the substrate 102 is heated to and maintained at a prescribed temperature by actuating the heater 104 provided in the substrate holder 103. Thereafter, the introduction of the He gas into the film-forming vessel 101 is terminated and simultaneously with this, for instance, SiH₄ gas and H₂ gas from the raw material gas supply system 114 are together introduced into the film-forming vessel 101 at prescribed respective flow rates through the raw material gas introduction pipe 115, and the inner pressure (the gas pressure) of the film-forming vessel 101 is adjusted to and maintained at a prescribed value by regulating the opening of the throttle valve 118. To the discharge electrode 105 (which is opposed to the substrate 102 while having a prescribed interval between the discharge electrode and the substrate), a high frequency power (with a prescribed frequency) of a prescribed wattage from the high frequency power source 107 is applied through the matching circuit 108 and the block condenser 109. At the same time, to the auxiliary electrode 110 (which is arranged between the substrate 102 and the heater 104 preferably such that it is approximately perpendicular to the gas flow), a prescribed periodicity voltage having at least two different waveform components having a different amplitude is applied by means of the power amplifier 111 and the high frequency signal generator 112. By this, glow discharge is generated to produce a plasma in the presence of the raw material gas in the space between the substrate and the discharge electrode of the film-forming chamber, whereby the raw material gas is decomposed to form a non-single crystal silicon deposited film on the substrate 102.

In the following, the features and advantages of the present invention will be described in more detail with reference to examples. It should be understood that these examples are only for illustrative purposes and are not intended to restrict the scope of the present invention to them.

Examples A1 to A4 are of the first aspect of the present invention, and Examples B1 to B4 are of the second aspect of the present invention.

### EXAMPLE A1

In this example, the formation of a non-single crystal silicon deposited film was conducted using the film-forming apparatus shown in FIG. 1, where a periodicity voltage of providing a negative maximum value with respect to a potential difference to the potential of the plasma generated in the film-forming vessel 101 was applied to the auxiliary electrode 110 comprising a cylindrical electrode made of a stainless steel having a diameter of 5 mm and a length of 35 cm. And observation was conducted of the generation quantity of hydrogen radical (H*) and that of SiH radical (SiH*) in the vicinity of the substrate 102 with respect to maximum amplitudes of the voltage.

Separately, for the comparison purpose, the formation of a non-single crystal silicon deposited film was conducted using a conventional plasma CVD film-forming apparatus not having such auxiliary electrode as in the present invention, and observation was conducted of the generation quantity of hydrogen radical (H*) and that of SiH radical (SiH*) in the vicinity of the substrate.

The formation of a non-single crystal silicon deposited film using the film-forming apparatus shown in FIG. 1 in this example was conducted as will be described below.

(1) A stainless steel substrate having a thickness of 0.15 mm and a size of 30 cm×30 cm [made of a stainless steel SUS430-BA (trademark name)] as the substrate 102 was fixed onto the substrate holder 103 (made of a stainless steel) in the film-forming vessel 101 such that the substrate was in an electrically earthed state.

The inside of the film-forming vessel 101 was evacuated to a vacuum of less than 1 Pa through the exhaust pipe 117 by actuating the exhaustion device 116.

(2) While continuing the evacuation operation, He gas from the raw material gas supply system 114 was introduced into the film-forming vessel 101 at a flow rate of 100 ml/minute (normal) through the raw material gas introduction pipe 115, and the inner pressure (the gas pressure) of the film-forming vessel 101 was maintained at 100 Pa by regulating the opening of the throttle valve 118.

(3) While maintaining the inner pressure of the film-forming vessel at aforesaid value, the stainless steel substrate 102 was heated at 300° C. for about 60 minutes by means of the heater 104 provided in the substrate holder 103 so that the entirety of the substrate was uniformly heated. While maintaining the substrate at this temperature, the introduction of the He gas into the film-forming vessel 101 was terminated and simultaneously with this, SiH₄ gas and H₂ gas from the raw material gas supply system 114 were together introduced into the film-forming vessel 101 at respective flow rates of 300 ml/minutes (normal) and 1200 ml/minute (normal) through the raw material gas introduction pipe 115, and the inner pressure (the gas pressure) of the film-forming vessel 101 was adjusted to and maintained at 266 Pa by regulating the opening of the throttle valve 118.

(4) To the discharge electrode 105 shaped in a plate form made of an aluminum (which is provided to oppose to the film-forming face of the substrate 102 while having an interval of 1.5 cm between the discharge electrode and the substrate), a high frequency power (with a frequency of 40 MHz) of 500 W from the high frequency power source 107 to which the high frequency signal generator 119 is connected was applied through the matching circuit 108 and the block condenser 109. At the same time, to the auxiliary electrode 110 comprising the foregoing stainless steel cylindrical electrode (which is arranged at a central position of a line formed by connecting the center of the film-forming face of the substrate 102 and the front face of the discharge electrode 105 such that the auxiliary electrode is in parallel to the substrate and also to the discharge electrode and it is approximately perpendicular to the direction of the gas flow in the film-forming vessel 101), a high frequency voltage of 1 MHz having a rectangular waveform with a duty ratio of 50% was applied by means of the high speed power amplifier 4055 (produced by NF CIRCUIT DESIGN BLOCK Company)] as the power amplifier 111 and the multifunction synthesizer wave factory 1952 (produced by NF CIRCUIT DESIGN BLOCK Company)] as the high frequency signal generator 112, so that a maximum voltage became to be 5 V or less smaller than the potential of a plasma generated in the film-forming vessel. By this, glow discharge was generated to produce a plasma in the presence of the raw material gas (comprising a mixture of SiH₄ gas and H₂ gas) in the space (that is, the plasma generation region) between the substrate and the discharge electrode in the film-forming vessel, whereby the raw material gas was decomposed to form an amorphous silicon deposited film on the substrate 102.

During the above film formation, the surface potential of the auxiliary electrode 110 was measured by means of the oscilloscope 113. And the quantity of hydrogen radical (H*) and that of SiH radical (SiH*) generated in the vicinity of the substrate were measured by way of real-time monitoring by means of a plasma emission spectrometer MAX-3000 (produced by ATAGOBUSSAN Kabushiki Kaisha).

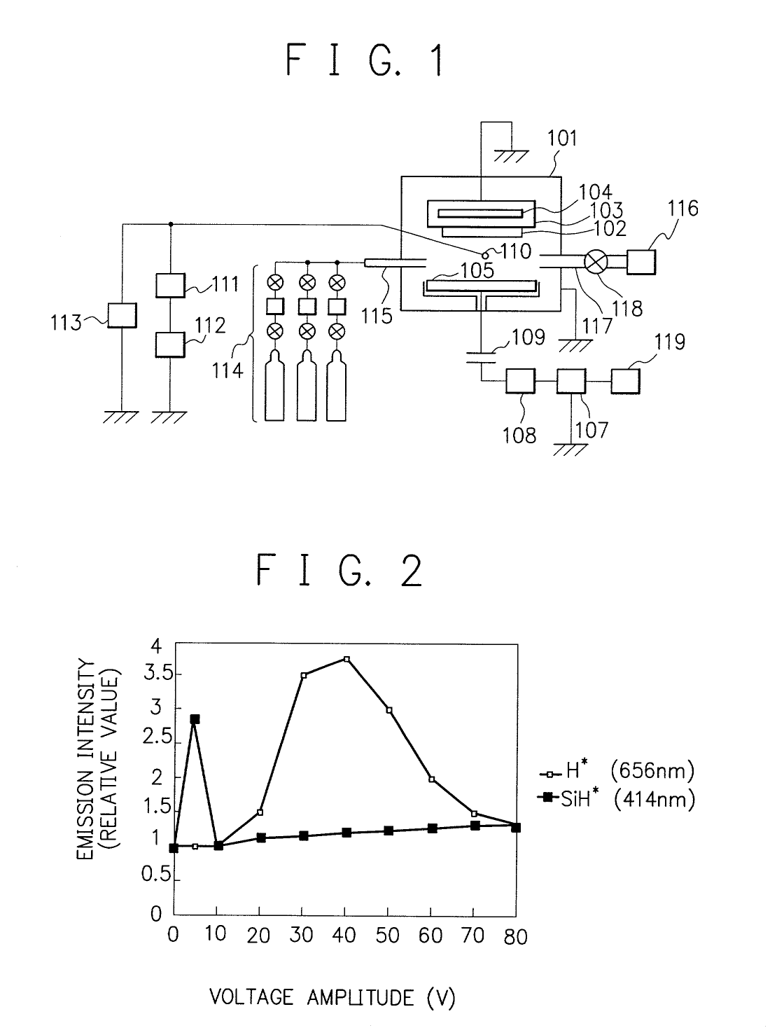

FIG. 2 is a graph showing observed transitions of an emission intensity of 656 nm indicating the quantity of hydrogen radical (H*) generated in the vicinity of the substrate and of an emission intensity of 414 nm indicating the quantity of SiH radical (SiH*) generated in the vicinity of the substrate, respectively in relation to the voltage amplitudes applied to the auxiliary electrode 110. The emission intensity values shown in FIG. 2 are relative values. Particularly, as a comparative example, using a modification of the film-forming apparatus shown in FIG. 1 in that the auxiliary electrode 110, the power amplifier 111, the high frequency signal generator 112, and the oscilloscope 113 are omitted, an amorphous silicon deposited film was formed on the substrate 102 as well as in Example 1A, where the quantity of hydrogen radical (H*) and that of SiH radical (SiH*) were measured in the same manner as in Example 1A.

The emission intensity values of H* in FIG. 2 are values relative to those in the comparative example, which are respectively set at 1, and similarly, the emission intensity values of SiH* in FIG. 2 are values relative to those in the comparative example, which are respectively set at 1.

Based on the results shown in FIG. 2, there was obtained a finding that SiH* is efficiently generated when the voltage amplitude applied to the auxiliary electrode is about 5 V, and H* is efficiently generated when the voltage amplitude applied to the auxiliary electrode is about 40 V.

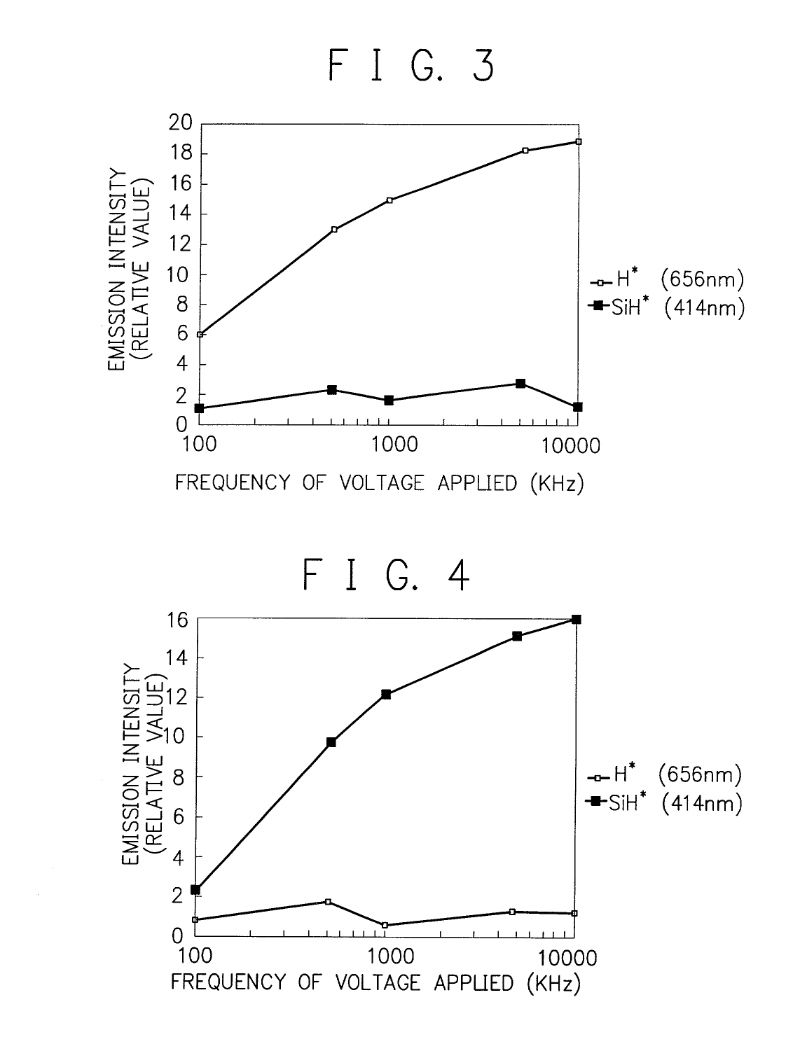

Accordingly, under the same conditions in the above film formation in Example A1 except that the voltage amplitude applied was fixed at 40 V and the frequency of the voltage applied was varied, the emission intensity of H* and that of SiH* generated in the vicinity of the substrate were measured. The results obtained are graphically shown in FIG. 3. Similarly, under the same conditions in the above film formation in Example A1 except that the voltage amplitude applied was fixed at 5 V and the frequency of the voltage applied was varied, the emission intensity of H* and that of SiH* generated in the vicinity of the substrate were measured. The results obtained are graphically shown in FIG. 4. The values shown in FIG. 3 and FIG. 4 are relative values as well as in FIG. 2.

Based on the results shown in FIG. 3 and FIG. 4, there were obtained the following findings.

That is, by changing the number of voltage application repetitive cycles per an unite time for the applied voltage which efficiently generates H*, the quantity of H* generated can be controlled without changing the quantity of SiH* generated.

Reversely, by changing the number of voltage application repetitive cycles per an unite time for the applied voltage which efficiently generates SiH*, the quantity of SiH* generated can be controlled without changing the quantity of H* generated.

These findings brought about an idea to use a periodicity voltage comprising a combination of the applied voltage (5 V) which efficiently generates SiH* and the applied voltage (40 V) which efficiently generates H*. As specific examples of such periodicity voltage, there were designed four kinds of periodicity voltages shown in FIGS. 5 to 8 (waveform A, waveform B, waveform C, and waveform D). And the foregoing film-forming procedures were repeated four times, wherein in each case, one of the four periodicity voltages shown in FIGS. 5 to 8 was applied to the auxiliary electrode during the film formation in order to examine the possibility of individually controlling the quantity of SiH* and that of H* generated in the vicinity of the substrate.

Here, in each of the waveforms shown in FIGS. 5 to 8, a peak portion of 40 V corresponds a waveform component having an amplitude where a change rate in the quantity of generated hydrogen radical (H*) of hydrogen becomes greater than that in the quantity of generated radical (chiefly SiH*) of a silane compound, and a peak portion of 5 V corresponds a waveform component having an amplitude where a change rate in the quantity of the latter radical becomes greater than that in the quantity of the former radial.

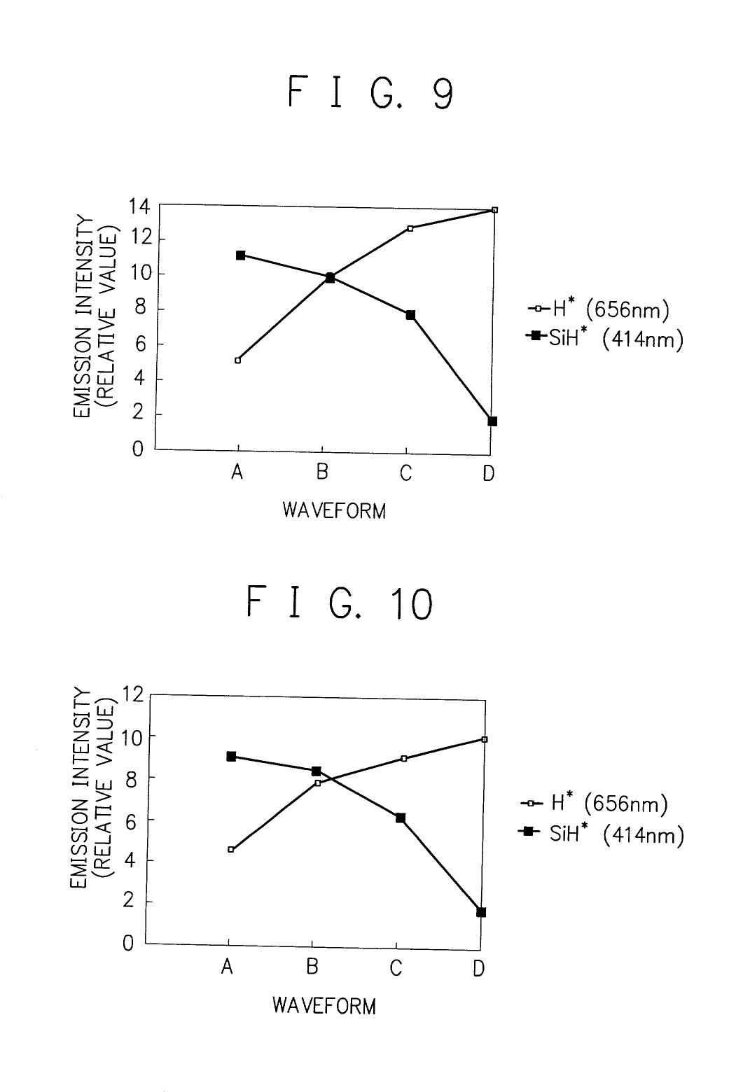

The examined results obtained in the above are graphically shown in FIG. 9. The values shown in FIG. 9 are relative values as well as in FIG. 2.

As the results shown in FIG. 9 illustrate, it is understood that by applying a periodicity voltage having at least two different waveform components having a different amplitude (a voltage lapse between adjacent peaks imparting an amplitude in a voltage-time curve) in one voltage application repetitive cycle to the auxiliary electrode 110, the quantities of the principal precursors in the plasma can be individually controlled.

### EXAMPLE A2

In this example, examination was conducted of the case where the frequency of the high frequency power applied to the discharge electrode 105 was made to be 60 MHz. Particularly, the film-forming procedures of Example A1 were repeated except that the frequency of the high frequency power applied to the discharge electrode 105 was changed to 60 MHz, the flow rate of the H₂ gas was changed to 600 ml/minute (normal), and the inner pressure of the film-forming vessel upon the film formation was changed to 133 Pa. The film-forming procedures are repeated four times. In each case, one of the periodicity voltage of the waveform A, the periodicity voltage of the waveform B, the periodicity voltage of the waveform C, and the periodicity voltage of the waveform D was applied to the auxiliary electrode 110 in order to examine the possibility of individually controlling the quantity of SiH* and that of H* generated in the vicinity of the substrate, as well as in Example A1.

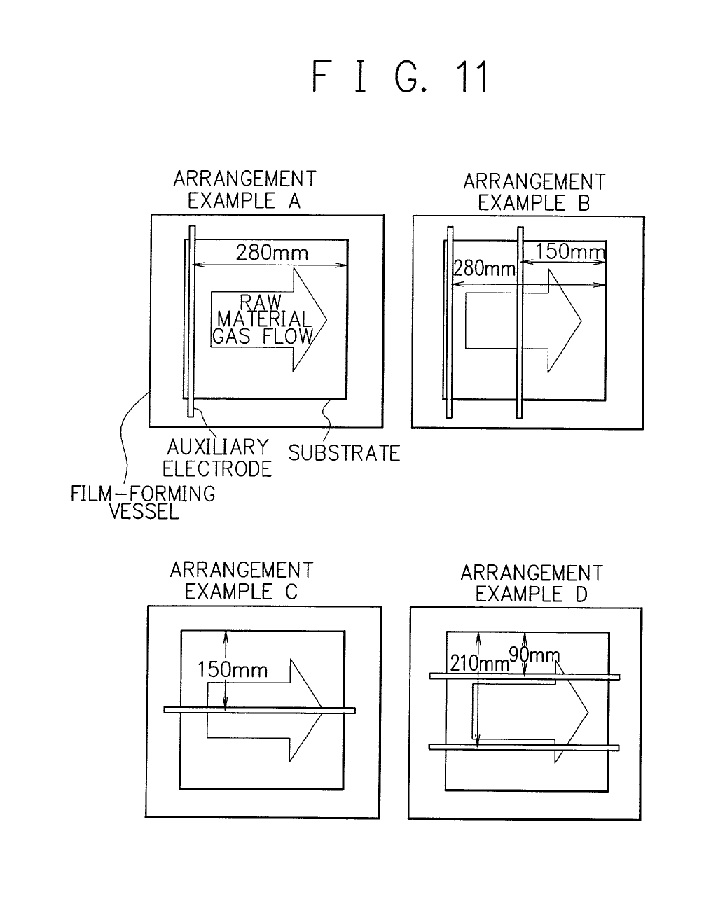

The examined results are graphically shown in FIG. 10. The values shown in FIG. 10 are relative values as well as in FIG. 2.

As the results shown in FIG. 10 illustrate, it is understood that even when the frequency of the high frequency power applied to the discharge electrode 105 is changed to 60 MHz, the quantities of the principal precursors in the plasma can be individually controlled as well as in Example 1A.

### EXAMPLE A3

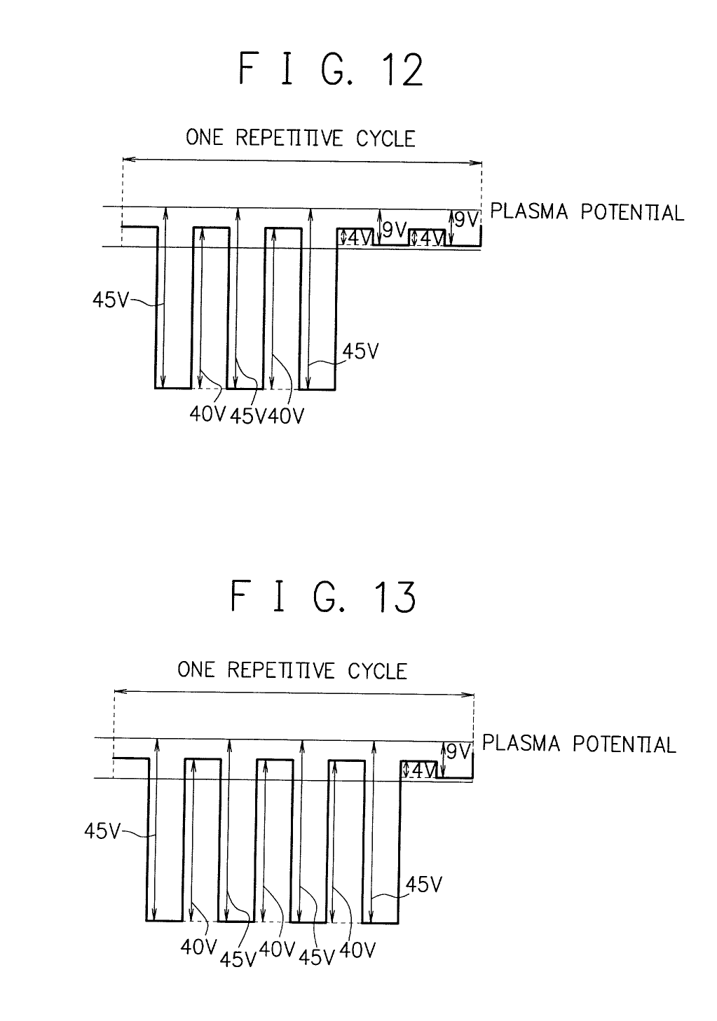

In accordance with the procedures of forming an amorphous silicon deposited film of Example A1 except for applying a periodicity voltage of a waveform shown in FIG. 12 to the auxiliary electrode 110 and changing the installation position of the auxiliary electrode as shown in one of Arrangement Examples A to D shown in FIG. 11, there was formed a semiconductor layer for a photovoltaic element, comprising an n-type amorphous silicon (a-Si) film, an i-type amorphous silicon (a-Si) film and a p-type amorphous silicon (a-Si) film sequentially formed on a stainless steel substrate having a thickness of 0.15 mm and a size of 30 cm×30 cm [made of a stainless steel SUS430-BA (trademark name)] as the substrate 102 under conditions shown in Table 1.

In the above, at a stage prior to forming the formation of the i-type a-Si film after the formation of the n-type a-Si film and also at a stage prior to forming the formation of the p-type a-Si film after the formation of the i-type a-Si film, the inside of the film-forming vessel 101 was sufficiently evacuated and purged several times by He gas.

After the completion of the semiconductor layer on the substrate 102, the substrate 102 having the semiconductor layer formed thereon was cooled to room temperature, and it was taken out from the film-forming apparatus. Then, using a conventional vacuum evaporation apparatus, an ITO transparent conductive film having a thickness of 70 nm was formed on the entire surface of the semiconductor layer on the substrate to obtain an element having a size of 30 cm×30 cm. The resultant element was cut into 100 elements having a size of about 30 mm× about 30 mm. Then, on the ITO transparent conductive film of each element, there was formed a 0.1 mm thick Ag-collecting electrode shaped in a comb form using an Ag-paste by means of screen printing. Thus, there were obtained 100 photovoltaic elements.

For the resultant 100 photovoltaic elements, their photoelectric conversion efficiencies were measured by a conventional manner. Particularly, for each of 10 sample groups comprising 10 photovoltaic elements situated in a direction perpendicular to the direction of the raw material gas flown in the film-forming vessel, an average value of the 10 photoelectric conversion efficiencies of the 10 photovoltaic elements of each group was obtained. For the resultant 10 average values, there was calculated a value of (the maximum value−the minimum value)/(the maximum value + the minimum value) in terms of a variation in the raw material gas flow direction. The resultant value was made to be a variation of the characteristics (the photoelectric conversion efficiencies) of the photovoltaic elements obtained.

The above procedures were repeated for each of Arrangement Example A, Arrangement Example B, Arrangement Example C, and Arrangement Example D shown in FIG. 11. In Arrangement Example A, one auxiliary electrode is arranged at a position in an upstream side of the substrate with respect to the raw material gas flow such that it is in parallel to the substrate with respect to the width direction thereof and perpendicular to the direction of the raw material gas flow. In Arrangement Example B, two auxiliary electrodes are arranged such that one auxiliary electrode is situated at a position in an upstream side of the substrate with respect to the raw material gas flow such that it is in parallel to the substrate with respect to the width direction thereof and perpendicular to the direction of the raw material gas flow and the other auxiliary electrode is situated at a central position of the substrate with respect to the length thereof such that it is in parallel to the substrate with respect to the width direction thereof and perpendicular to the direction of the raw material gas flow. In Arrangement Example C, one auxiliary electrode is arranged at a central position of the substrate with respect to the width of the substrate such that it is in parallel to the substrate with respect to the longitudinal direction there on and is also in parallel to the direction of the raw material gas flow. In Arrangement Example D, two auxiliary electrodes are arranged such that one auxiliary electrode is situated at a position in one side of the substrate with respect to the width thereof such that it is in parallel to the substrate with respect to the longitudinal direction and is also in parallel to the direction of the raw material gas flow and the other auxiliary electrode is situated at a position in the other side of the substrate with respect to the width thereof such that it is in parallel to the substrate with respect to the longitudinal direction and is also in parallel to the direction of the raw material gas flow.

For each of these four cases, there were obtained 100 photovoltaic elements, and for the resultant photovoltaic elements, (a) a variation of their photoelectric conversion efficiencies in the raw material gas flow direction was obtained. Separately, for each of four cases in which no auxiliary electrode was used, which are corresponding to the above four cases, there were obtained 100 photovoltaic elements, and for the resultant photovoltaic elements, there was obtained (a′) a variation of their photoelectric conversion efficiencies in the raw material gas flow direction. And there was obtained a ratio of the variation (a) to the variation (a′) for each case. The results obtained are shown in Table 2.

Separately, for the 100 photovoltaic elements obtained in each of the four cases in which the auxiliary electrode(s) was used, there were obtained (b) an average photoelectric conversion efficiency and (c) an average film deposition rate. Similarly, for the 100 photovoltaic elements obtained in each of the four cases in which no auxiliary electrode was used, there were obtained (b′) an average photoelectric conversion efficiency and (c′) an average film deposition rate. And there were obtained a ratio of the average photoelectric conversion efficiency (b) to the average photoelectric conversion efficiency (b′) in each case and a ratio of the film deposition rate (c) to the average film deposition rate (c′) in each case. The results obtained are shown in Table 2.

As the results shown in Table 2 illustrate, it is understood that according to the film-forming method of the first aspect of the present invention, it is possible to efficiently form a high quality large area functional deposited film having a homogeneous property over the entire area and an uniform property distribution also in the raw material gas flow direction at a high film deposition rate. It is also understood that good results are afforded when the auxiliary electrode is arranged to be in parallel to the substrate and perpendicular to the direction of the raw material gas flow.

For the reason for this, it is considered such that the precursors including the hydrogen radicals (which contribute to forming a deposited film) generated in the vicinity of the auxiliary electrode were uniformly supplied to the entirety of a surface of the substrate situated in a downstream side of the location of the auxiliary electrode with respect to the direction of the raw material gas flow.

And for the case where the auxiliary electrode is arranged to be in parallel to the direction of the raw material gas flow, it is understood that the results afforded are inferior to those afforded in the case where the auxiliary electrode is arranged to be in parallel to the substrate and perpendicular to the direction of the raw material gas flow.

### EXAMPLE A4

In accordance with the procedures of forming an amorphous silicon deposited film of Example A1 except that the installation position of the auxiliary electrode was made as shown in Arrangement Example B of FIG. 11, and a periodicity voltage of a waveform shown in FIG. 13 was applied to the auxiliary electrode 110, there was formed a 7 nm thick microcrystalline silicon deposited film formed on a stainless steel substrate having a thickness of 0.15 mm and a size of 30 cm×30 cm [made of a stainless steel SUS430-BA (trademark name)] as the substrate 102 under conditions shown in Table 3.

The substrate having the microcrystalline silicon deposited film formed thereon was cut into 100 samples having a size of about 30 mm×30 mm.

For each of the 100 samples, its crystal deposition rate was examined by obtaining a Raman scattering spectrum by means of a conventional laser Raman spectrometer and observing an intensity ratio between a sharp signal from near 520 cm⁻¹ in the Raman scattering spectrum which is corresponding to a crystal and abroad signal from near 480 cm⁻¹ in the Raman scattering spectrum which is corresponding to an amorphous material. And for the resultant 100 intensity ratios, there was obtained (a) an average intensity ratio.

Separately, the above film-forming procedures were repeated, except that no periodicity voltage was applied to the auxiliary electrode, to form a 7 nm thick microcrystalline silicon deposited film on a stainless steel substrate which is the same as in the above. The substrate having the microcrystalline silicon deposited film formed thereon was cut into 100 samples having a size of about 30 mm×30 mm. For the resultant 100 samples, there was obtained (a′) an average intensity ratio in the same manner as in the above.

As a result of having compared the average intensity ratio (a) with that (a′), there was obtained a finding that the crystal deposition rate of a microcrystalline silicon deposited film formed on a substrate in the case where a prescribed periodicity voltage is applied to the auxiliary electrode is increased by 20% in comparison with that in the case where no periodicity voltage is applied to the auxiliary electrode.

This finding indicates that the film-forming method of the first aspect of the present invention makes it possible to form a large area microcrystalline silicon deposited film at an improved crystal deposition rate.

### EXAMPLE B1

In this example, the formation of a non-single crystal silicon deposited film was conducted using the film-forming apparatus shown in FIG. 14, where a periodicity voltage of providing a negative maximum value with respect to a potential difference to the potential of the plasma generated in the film-forming vessel 101 was applied to the auxiliary electrode 110 comprising a cylindrical electrode made of a stainless steel having a diameter of 5 mm and a length of 35 cm. And observation was conducted of the generation quantity of hydrogen radical (H*) and that of SiH radical (SiH*) in the vicinity of the substrate 102 with respect to maximum amplitudes of the voltage.

Separately, for the comparison purpose, the formation of a non-single crystal silicon deposited film was conducted using a conventional plasma CVD film-forming apparatus not having such auxiliary electrode as in the present invention, and observation was conducted of the generation quantity of hydrogen radical (H*) and that of SiH radical (SiH*) in the vicinity of the substrate.

The formation of a non-single crystal silicon deposited film using the film-forming apparatus shown in FIG. 14 in this example was conducted as will be described below.

(1) A stainless steel substrate having a thickness of 0.15 mm and a size of 30 cm×30 cm [made of a stainless steel SUS430-BA (trademark name)] as the substrate 102 was fixed onto the substrate holder 103 (made of a stainless steel) in the film-forming vessel 101 such that the substrate was in a floating potential state.

The inside of the film-forming vessel 101 was evacuated to a vacuum of less than 1 Pa through the exhaust pipe 117 by actuating the exhaustion device 116.

(2) While continuing the evacuation operation, He gas from the raw material gas supply system 114 was introduced into the film-forming vessel 101 at a flow rate of 100 ml/minute (normal) through the raw material gas introduction pipe 115, and the inner pressure (the gas pressure) of the film-forming vessel 101 was maintained at 100 Pa by regulating the opening of the throttle valve 118.

(3) While maintaining the inner pressure of the film-forming vessel at aforesaid value, the stainless steel substrate 102 was heated at 300° C. for about 60 minutes by means of the heater 104 provided in the substrate holder 103 so that the entirety of the substrate was uniformly heated. While maintaining the substrate at this temperature, the introduction of the He gas into the film-forming vessel 101 was terminated and simultaneously with this, SiH₄ gas and H₂ gas from the raw material gas supply system 114 were together introduced into the film-forming vessel 101 at respective flow rates of 300 ml/minutes (normal) and 1200 ml/minute (normal) through the raw material gas introduction pipe 115, and the inner pressure (the gas pressure) of the film-forming vessel 101 was adjusted to and maintained at 266 Pa by regulating the opening of the throttle valve 118.

(4) To the discharge electrode 105 shaped in a plate form made of an aluminum (which is provided to oppose to the film-forming face of the substrate 102 while having an interval of 1.5 cm between the discharge electrode and the substrate), a high frequency power (with a frequency of 40 MHz) of 500 W from the high frequency power source 107 to which the high frequency signal generator 119 is connected was applied through the matching circuit 108 and the block condenser 109. At the same time, to the auxiliary electrode 110 comprising the foregoing stainless steel cylindrical electrode (which is arranged between the substrate 102 and the heater 104 so as to be approximately perpendicular to the direction of the gas flow in the film-forming vessel 101), a high frequency voltage of 1 MHz having a rectangular waveform with a duty ratio of 50% was applied by means of the high speed power amplifier 4055 (produced by NF CIRCUIT DESIGN BLOCK Company)] as the power amplifier 111 and the multifunction synthesizer wave factory 1952 (produced by NF CIRCUIT DESIGN BLOCK Company)] as the high frequency signal generator 112, so that a maximum voltage became to be 5 V or less smaller than the potential of a plasma generated in the film-forming vessel. By this, glow discharge was generated to produce a plasma in the presence of the raw material gas (comprising a mixture of SiH₄ gas and H₂ gas) in the space (that is, the plasma generation region) between the substrate and the discharge electrode in the film-forming vessel, whereby the raw material gas was decomposed to form an amorphous silicon deposited film on the substrate 102.

During the above film formation, the surface potential of the auxiliary electrode 110 was measured by means of the oscilloscope 113. And the quantity of hydrogen radical (H*) and that of SiH radical (SiH*) generated in the vicinity of the substrate were measured by way of real-time monitoring by means of a plasma emission spectrometer MAX-3000 (produced by ATAGOBUSSAN Kabushiki Kaisha).

FIG. 15 is a graph showing observed transitions of an emission intensity of 656 nm indicating the quantity of hydrogen radical (H*) generated in the vicinity of the substrate and of an emission intensity of 414 nm indicating the quantity of SiH radical (SiH*) generated in the vicinity of the substrate, respectively in relation to the voltage amplitudes applied to the auxiliary electrode 110. The emission intensity values shown in FIG. 15 are relative values. Particularly, as a comparative example, using a modification of the film-forming apparatus shown in FIG. 14 in that the auxiliary electrode 110, the power amplifier 111, the high frequency signal generator 112, and the oscilloscope 113 are omitted, an amorphous silicon deposited film was formed on the substrate 102 as well as in Example B1, where the quantity of hydrogen radical (H*) and that of SiH radical (SiH*) were measured in the same manner as in Example B1.

The emission intensity values of H* in FIG. 15 are values relative to those in the comparative example, which are respectively set at 1, and similarly, the emission intensity values of SiH* in FIG. 15 are values relative to those in the comparative example, which are respectively set at 1.

Based on the results shown in FIG. 15, there was obtained a finding that SiH* is efficiently generated when the voltage amplitude applied to the auxiliary electrode is about 10 V, and H* is efficiently generated when the voltage amplitude applied to the auxiliary electrode is about 45 V.

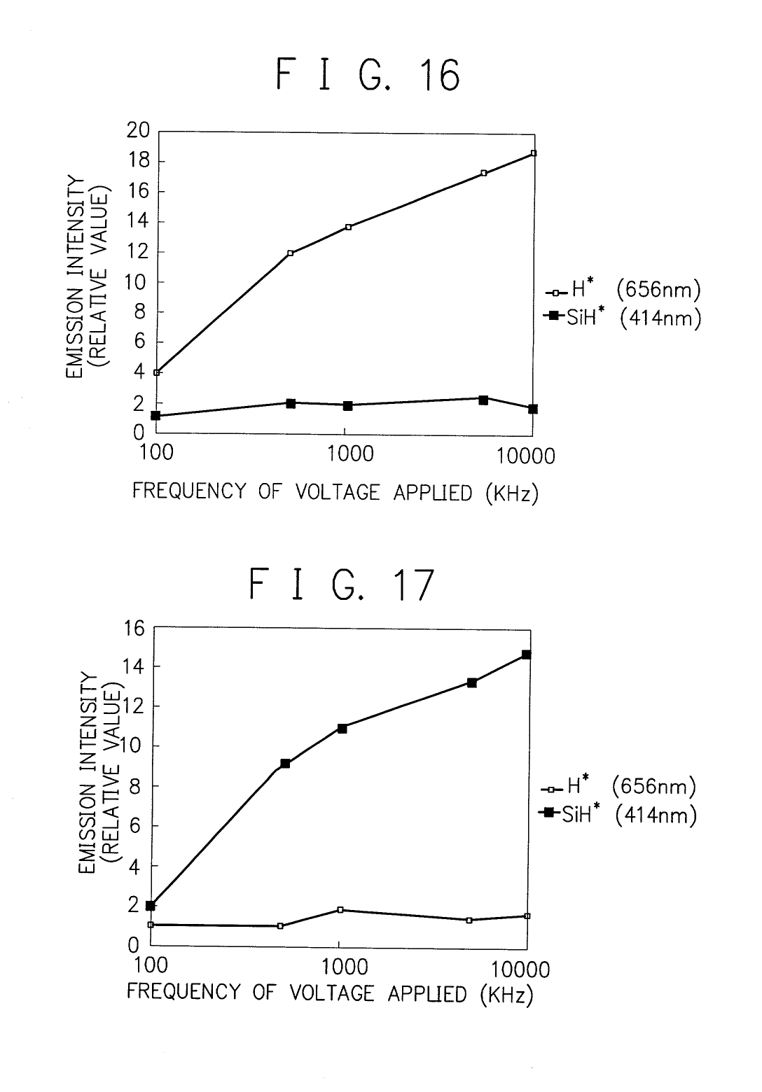

Accordingly, under the same conditions in the above film formation in Example B1 except that the voltage amplitude applied was fixed at 45 V and the frequency of the voltage applied was varied, the emission intensity of H* and that of SiH* generated in the vicinity of the substrate were measured. The results obtained are graphically shown in FIG. 16. Similarly, under the same conditions in the above film formation in Example B1 except that the voltage amplitude applied was fixed at 10 V and the frequency of the voltage applied was varied, the emission intensity of H* and that of SiH* generated in the vicinity of the substrate were measured. The results obtained are graphically shown in FIG. 17. The values shown in FIG. 16 and FIG. 17 are relative values as well as in FIG. 15.

Based on the results shown in FIG. 16 and FIG. 17, there were obtained the following findings.

That is, by changing the number of voltage application repetitive cycles per an unite time for the applied voltage which efficiently generates H*, the quantity of H* generated can be controlled without changing the quantity of SiH* generated.

Reversely, by changing the number of voltage application repetitive cycles per an unite time for the applied voltage which efficiently generates SiH*, the quantity of SiH* generated can be controlled without changing the quantity of H* generated.

These findings brought about an idea to use a periodicity voltage comprising a combination of the applied voltage (10 V) which efficiently generates SiH* and the applied voltage (45 V) which efficiently generates H*. As specific examples of such periodicity voltage, there were designed four kinds of periodicity voltages shown in FIGS. 18 to 21 (waveform A, waveform B, waveform C, and waveform D). And the foregoing film-forming procedures were repeated four times, wherein in each case, one of the four periodicity voltages shown in FIGS. 18 to 21 was applied to the auxiliary electrode during the film formation in order to examine the possibility of individually controlling the quantity of SiH* and that of H* generated in the vicinity of the substrate.

Here, in each of the waveforms shown in FIGS. 18 to 21, a peak portion of 45 V corresponds a waveform component having an amplitude where a change rate in the quantity of generated hydrogen radical (H*) of hydrogen becomes greater than that in the quantity of generated radical (chiefly SiH*) of a silane compound, and a peak portion of 10 V corresponds a waveform component having an amplitude where a change rate in the quantity of the latter radical becomes greater than that in the quantity of the former radial.

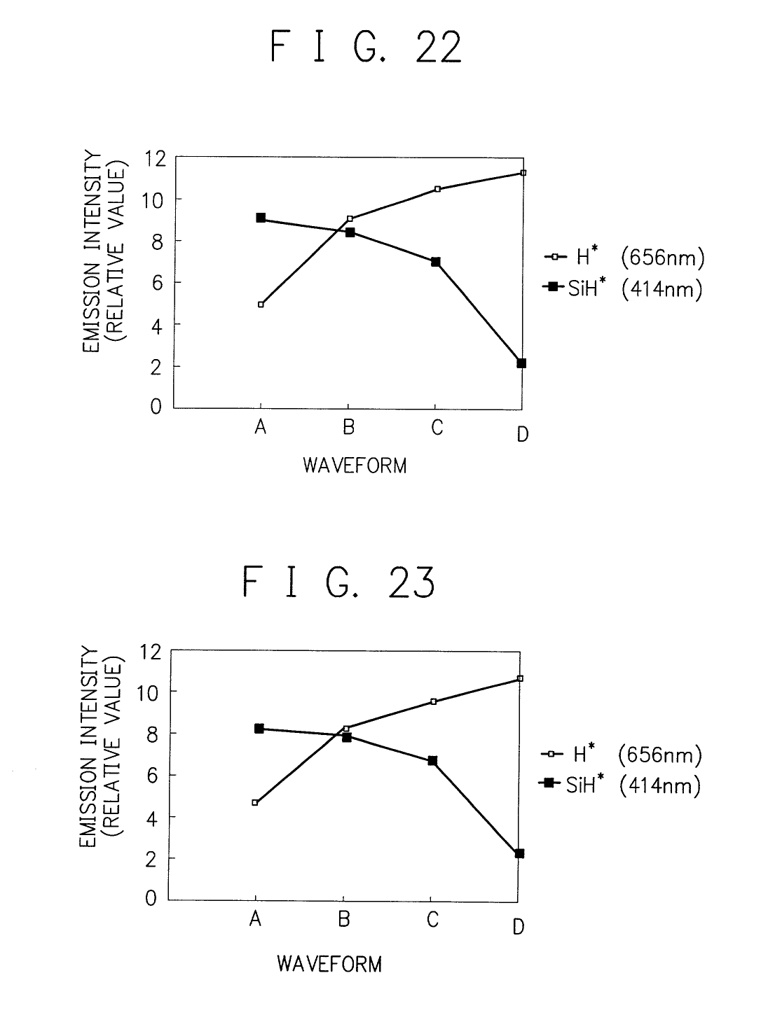

The examined results obtained in the above are graphically shown in FIG. 22. The values shown in FIG. 22 are relative values as well as in FIG. 15.

As the results shown in FIG. 22 illustrate, it is understood that by applying a periodicity voltage having at least two different waveform components having a different amplitude (a voltage lapse between adjacent peaks imparting an amplitude in a voltage-time curve) in one voltage application repetitive cycle to the auxiliary electrode 110, the quantities of the principal precursors in the plasma can be individually controlled.

### EXAMPLE B2

In this example, examination was conducted of the case where the frequency of the high frequency power applied to the discharge electrode 105 was made to be 60 MHz. Particularly, the film-forming procedures of Example B1 were repeated except that the frequency of the high frequency power applied to the discharge electrode 105 was changed to 60 MHz, the flow rate of the H₂ gas was changed to 600 ml/minute (normal), and the inner pressure of the film-forming vessel upon the film formation was changed to 133 Pa. The film-forming procedures are repeated four times. In each case, one of the periodicity voltage of the waveform A, the periodicity voltage of the waveform B, the periodicity voltage of the waveform C, and the periodicity voltage of the waveform D was applied to the auxiliary electrode 110 in order to examine the possibility of individually controlling the quantity of SiH* and that of H* generated in the vicinity of the substrate, as well as in Example B1.

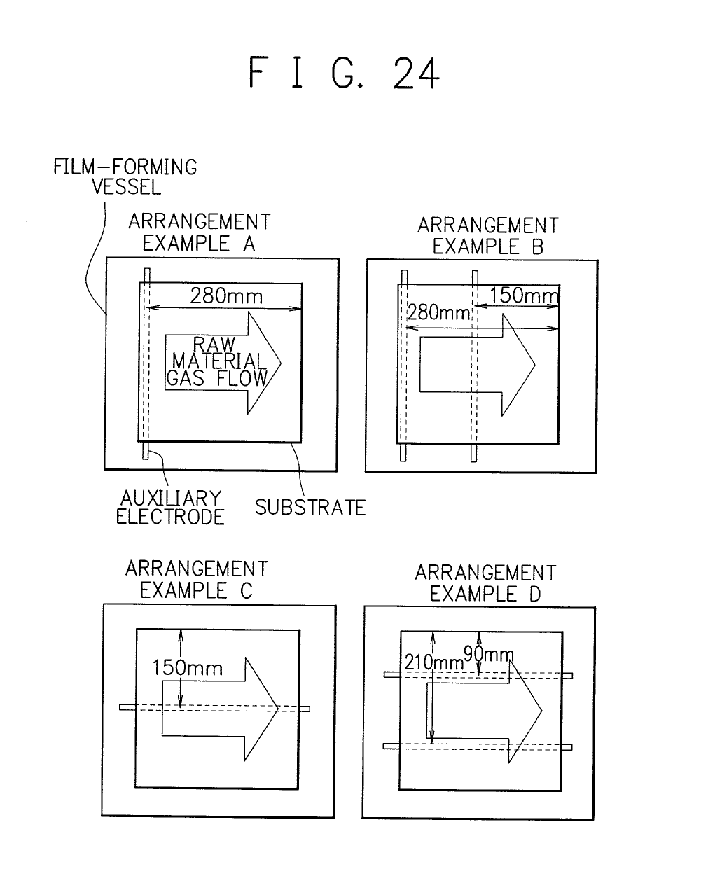

The examined results are graphically shown in FIG. 23. The values shown in FIG. 23 are relative values as well as in FIG. 15.

As the results shown in FIG. 23 illustrate, it is understood that even when the frequency of the high frequency power applied to the discharge electrode 105 is changed to 60 MHz, the quantities of the principal precursors in the plasma can be individually controlled as well as in Example B1.

### EXAMPLE B3

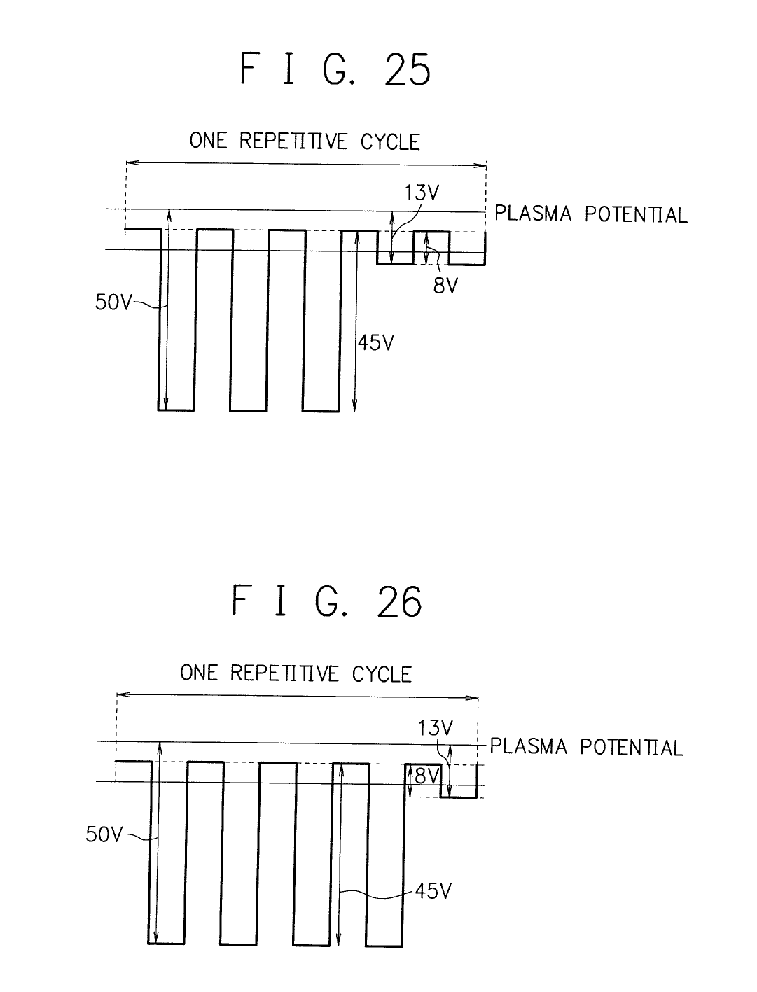

In accordance with the procedures of forming an amorphous silicon deposited film of Example B1 except for applying a periodicity voltage of a waveform shown in FIG. 25 to the auxiliary electrode 110 and changing the installation position of the auxiliary electrode as shown in one of Arrangement Examples A to D shown in FIG. 24, there was formed a semiconductor layer for a photovoltaic element, comprising an n-type amorphous silicon (a-Si) film, ani-type amorphous silicon (a-Si) film and a p-type amorphous silicon (a-Si) film sequentially formed on a stainless steel substrate having a thickness of 0.15 mm and a size of 30 cm×30 cm [made of a stainless steel SUS430-BA (trademark name)] as the substrate 102 under conditions shown in Table 4.

In the above, at a stage prior to forming the formation of the i-type a-Si film after the formation of the n-type a-Si film and also at a stage prior to forming the formation of the p-type a-Si film after the formation of the i-type a-Si film, the inside of the film-forming vessel 101 was sufficiently evacuated and purged several times by He gas.

After the completion of the semiconductor layer on the substrate 102, the substrate 102 having the semiconductor layer formed thereon was cooled to room temperature, and it was taken out from the film-forming apparatus. Then, using a conventional vacuum evaporation apparatus, an ITO transparent conductive film having a thickness of 70 nm was formed on the entire surface of the semiconductor layer on the substrate to obtain an element having a size of 30 cm×30 cm. The resultant element was cut into 100 elements having a size of about 30 mm× about 30 mm. Then, on the ITO transparent conductive film of each element, there was formed a 0.1 mm thick Ag-collecting electrode shaped in a comb form using an Ag-paste by means of screen printing. Thus, there were obtained 100 photovoltaic elements.

For the resultant 100 photovoltaic elements, their photoelectric conversion efficiencies were measured by a conventional manner. Particularly, for each of 10 sample groups comprising 10 photovoltaic elements situated in a direction perpendicular to the direction of the raw material gas flown in the film-forming vessel, an average value of the 10 photoelectric conversion efficiencies of the 10 photovoltaic elements of each group was obtained. For the resultant 10 average values, there was calculated a value of (the maximum value−the minimum value)/(the maximum value+the minimum value) in terms of a variation in the raw material gas flow direction. The resultant value was made to be a variation of the characteristics (the photoelectric conversion efficiencies) of the photovoltaic elements obtained.

The above procedures were repeated for each of Arrangement Example A, Arrangement Example B, Arrangement Example C, and Arrangement Example D shown in FIG. 11. In Arrangement Example A, one auxiliary electrode is arranged at a position in an upstream side of the substrate with respect to the raw material gas flow such that it is in parallel to the substrate with respect to the width direction thereof and perpendicular to the direction of the raw material gas flow. In Arrangement Example B, two auxiliary electrodes are arranged such that one auxiliary electrode is situated at a position in an upstream side of the substrate with respect to the raw material gas flow such that it is in parallel to the substrate with respect to the width direction thereof and perpendicular to the direction of the raw material gas flow and the other auxiliary electrode is situated at a central position of the substrate with respect to the length thereof such that it is in parallel to the substrate with respect to the width direction thereof and perpendicular to the direction of the raw material gas flow. In Arrangement Example C, one auxiliary electrode is arranged at a central position of the substrate with respect to the width of the substrate such that it is in parallel to the substrate with respect to the longitudinal direction thereon and is also in parallel to the direction of the raw material gas flow. In Arrangement Example D, two auxiliary electrodes are arranged such that one auxiliary electrode is situated at a position in one side of the substrate with respect to the width thereof such that it is in parallel to the substrate with respect to the longitudinal direction and is also in parallel to the direction of the raw material gas flow and the other auxiliary electrode is situated at a position in the other side of the substrate with respect to the width thereof such that it is in parallel to the substrate with respect to the longitudinal direction and is also in parallel to the direction of the raw material gas flow.

For each of these four cases, there were obtained 100 photovoltaic elements, and for the resultant photovoltaic elements, (a) a variation of their photoelectric conversion efficiencies in the raw material gas flow direction was obtained. Separately, for each of four cases in which no auxiliary electrode was used, which are corresponding to the above four cases, there were obtained 100 photovoltaic elements, and for the resultant photovoltaic elements, there was obtained (a′) a variation of their photoelectric conversion efficiencies in the raw material gas flow direction. And there was obtained a ratio of the variation (a) to the variation (a′) for each case. The results obtained are shown in Table 5.

Separately, for the 100 photovoltaic elements obtained in each of the four cases in which the auxiliary electrode(s) was used, there were obtained (b) an average photoelectric conversion efficiency and (c) an average film deposition rate. Similarly, for the 100 photovoltaic elements obtained in each of the four cases in which no auxiliary electrode was used, there were obtained (b′) an average photoelectric conversion efficiency and (c′) an average film deposition rate. And there were obtained a ratio of the average photoelectric conversion efficiency (b) to the average photoelectric conversion efficiency (b′) in each case and a ratio of the film deposition rate (c) to the average film deposition rate (c′) in each case. The results obtained are shown in Table 5.

As the results shown in Table 5 illustrate, it is understood that according to the film-forming method of the second aspect of the present invention, it is possible to efficiently form a high quality large area functional deposited film having a homogeneous property over the entire area and an uniform property distribution also in the raw material gas flow direction at a high film deposition rate. It is also understood that good results are afforded when the auxiliary electrode is arranged to be in parallel to the substrate and perpendicular to the direction of the raw material gas flow.

For the reason for this, it is considered such that the precursors including the hydrogen radicals (which contribute to forming a deposited film) generated in the vicinity of the substrate were uniformly supplied to the entirety of a surface of the substrate situated in a downstream side of the location of the auxiliary electrode with respect to the direction of the raw material gas flow.

And for the case where the auxiliary electrode(s) is arranged to be in parallel to the direction of the raw material gas flow, it is understood that the results afforded are inferior to those afforded in the case where the auxiliary electrode is arranged to be in parallel to the substrate and perpendicular to the direction of the raw material gas flow.

### EXAMPLE B4

In accordance with the procedures of forming an amorphous silicon deposited film of Example B1 except that the installation position of the auxiliary electrode was made as shown in Arrangement Example B of FIG. 24, and a periodicity voltage of a waveform shown in FIG. 26 was applied to the auxiliary electrode 110, there was formed a 7 nm thick microcrystalline silicon deposited film formed on a stainless steel substrate having a thickness of 0.15 mm and a size of 30 cm×30 cm [made of a stainless steel SUS430-BA (trademark name)] as the substrate 102 under conditions shown in Table 6.

The substrate having the microcrystalline silicon deposited film formed thereon was cut into 100 samples having a size of about 30 mm×30 mm.

For each of the 100 samples, its crystal deposition rate was examined by obtaining a Raman scattering spectrum by means of a conventional laser Raman spectrometer and observing an intensity ratio between a sharp signal from near 520 cm⁻¹ in the Raman scattering spectrum which is corresponding to a crystal and a broad signal from near 480 cm⁻¹ in the Raman scattering spectrum which is corresponding to an amorphous material. And for the resultant 100 intensity ratios, there was obtained (a) an average intensity ratio.

Separately, the above film-forming procedures were repeated, except that no periodicity voltage was applied to the auxiliary electrode, to form a 7 nm thick microcrystalline silicon deposited film on a stainless steel substrate which is the same as in the above. The substrate having the microcrystalline silicon deposited film formed thereon was cut into 100 samples having a size of about 30 mm×30 mm. For the resultant 100 samples, there was obtained (a′) an average intensity ratio in the same manner as in the above.

As a result of having compared the average intensity ratio (a) with that (a′), there was obtained a finding that the crystal deposition rate of a microcrystalline silicon deposited film formed on a substrate in the case where a prescribed periodicity voltage is applied to the auxiliary electrode is increased by 20% in comparison with that in the case where no periodicity voltage is applied to the auxiliary electrode.

This finding indicates that the film-forming method of the second aspect of the present invention makes it possible to form a large area microcrystalline silicon deposited film at an improved crystal deposition rate.

As will be understood from the above description, the film-forming method of the first aspect of the present invention makes it possible that the hydrogen radical and the precursor (which contribute to forming a deposited film) are separately generated in a necessary quantity in the plasma generated in the plasma generation region. Because of this, it is possible to efficiently form a high quality large area amorphous silicon series deposited film having an excellent and uniform property distribution over the entirety thereof on a desired substrate at a high deposition rate. The film-forming method of the first aspect of the present invention makes it also possible to efficiently form a high quality large area microcrystalle silicon series deposited film having an excellent and uniform property distribution over the entirety thereof on a desired substrate while improving the crystallinity thereof. Similarly, the film-forming method of the second aspect of the present invention makes it possible that the hydrogen radical and the precursor (which contribute to forming a deposited film) are separately generated in a necessary quantity in the plasma generated in the plasma generation region. Because of this, it is possible to efficiently form a high quality large area amorphous silicon series deposited film having an excellent and uniform property distribution over the entirety thereof on a desired substrate at a high deposition rate. The film-forming method of the second aspect of the present invention makes it also possible to efficiently form a high quality large area microcrystalle silicon series deposited film having an excellent and uniform property distribution over the entirety thereof on a desired substrate while improving the crystallinity thereof. And the film-forming method of the second aspect of the present invention has an additional pronounced advantage in that any substrates comprising an appropriate material can be optionally adopted as the substrate for forming such deposited film because the auxiliary electrode is not provided in the plasma generation region to which the substrate is exposed, and the plasma generated in the plasma generation region is maintained in a stable state without being disturbed, where the electrons in the plasma can be efficiently accelerated by the action of the auxiliary electrode.

TABLE 1

| | the kind of a film formed & | | |
|---|---|---|---|
| | the thickness thereof | | |
| | n-type a-Si film | i-type a-Si film | p-type a-Si film |
| parameters | (30 nm) | (300 nm) | (10 nm) |
| raw material gas & | | | |
| its flow rate | | | |
| [ml/min (normal)] | | | |
| S i H₄ | 300 | 500 | 10 |
| H₂ | 1000 | 1000 | 3000 |
| PH₃ | 1 | — | — |
| BF₃ | — | — | 0.1 |
| inner pressure (Pa) | 133 | 133 | 133 |
| substrate temperature | 300 | 300 | 300 |
| (° C.) | | | |
| high frequency power | 500 | 500 | 1200 |
| (W) | | | |
| frequency (Hz) | 60 | 60 | 60 |
| applied voltage to the | | | |
| auxiliary electrode | | | |
| waveform | rectangular | rectangular | rectangular |
| (see, FIG. 12) | waveform | waveform | waveform |
| frequency (MHz) | 1 | 1 | 1 |
| voltage amplitude (V) | 4 & 40 | 4 & 40 | 4 & 40 |
| Vp − Vmax (V) * | 5 | 5 | 5 |

* Vp = plasma potential
Vmax = the maximum value of the applied voltage
Vp − Vmax = a potential difference

TABLE 2

| | | a ratio between | |
|---|---|---|---|
| | a ratio between | the two average | a ratio between |
| | the two average | photoelectric | the two average |
| | variations in the | conversion | film deposition |
| | gas flow direction | efficiencies | rates |
| Arrangement | 0.404 | 1.18 | 1.09 |
| Example A | | | |
| Arrangement | 0.071 | 1.36 | 1.10 |
| Experiment B | | | |
| Arrangement | 0.579 | 1.09 | 1.03 |
| Experiment C | | | |
| Arrangement | 0.321 | 1.19 | 1.10 |
| Experiment D | | | |

TABLE 3

| raw material gas & its flow rate | |
|---|---|
| [ml/min (normal)] | |
| S i H₄ | 50 |
| H₂ | 2000 |
| inner pressure (Pa) | 27 |
| substrate temperature (° C.) | 300 |
| high frequency power (W) | 1200 |
| frequency (Hz) | 80 |
| applied voltage to the auxiliary | |
| electrode | |
| waveform (see, FIG. 13) | rectangular waveform |
| frequency (MHz) | 1 |
| voltage amplitude (V) | 4 & 40 |
| Vp − Vmax (V) | 5 |

* Vp = plasma potential
Vmax = the maximum value of the applied voltage
Vp − Vmax = a potential difference

TABLE 4

| | the kind of a film formed & | | |
|---|---|---|---|
| | the thickness thereof | | |
| | n-type a-Si film | i-type a-Si film | p-type a-Si film |
| parameters | (30 nm) | (300 nm) | (10 nm) |
| raw material gas & | | | |
| its flow rate | | | |
| [ml/min (normal)] | | | |
| S i H₄ | 300 | 500 | 10 |
| H₂ | 1000 | 1000 | 3000 |
| PH₃ | 1 | — | — |
| BF₃ | — | — | 0.1 |
| inner pressure (Pa) | 133 | 133 | 133 |
| substrate temperature | 300 | 300 | 300 |
| (° C.) | | | |
| high frequency power | 500 | 500 | 1200 |
| (W) | | | |
| frequency (Hz) | 60 | 60 | 60 |
| applied voltage to the | | | |
| auxiliary electrode | | | |
| waveform | rectangular | rectangular | rectangular |
| (see, FIG. 25) | waveform | waveform | waveform |
| frequency (MHz) | 1 | 1 | 1 |
| voltage amplitude (V) | 8 & 45 | 8 & 45 | 8 & 45 |
| Vp − Vmax (V) * | 5 | 5 | 5 |

* Vp = plasma potential
Vmax = the maximum value of the applied voltage
Vp − Vmax = a potential difference

TABLE 5

| | | a ratio between | |
|---|---|---|---|
| | a ratio between | the two average | a ratio between |
| | the two average | photoelectric | the two average |
| | variations in the | conversion | film deposition |
| | gas flow direction | efficiencies | rates |
| Arrangement | 0.358 | 1.22 | 1.11 |
| Experiment A | | | |
| Arrangement | 0.053 | 1.40 | 1.21 |
| Experiment B | | | |
| Arrangement | 0.511 | 1.11 | 1.03 |
| Experiment C | | | |
| Arrangement | 0.297 | 1.22 | 1.10 |
| Experiment D | | | |
| Arrangement | 1.304 | 0.88 | 0.94 |
| Experiment E | | | |

TABLE 6

| raw material gas & its flow rate | |
|---|---|
| [ml/min (normal)] | |
| S i H₄ | 50 |
| H₂ | 2000 |
| inner pressure (Pa) | 25 |
| substrate temperature (° C.) | 300 |
| high frequency power (W) | 1200 |
| frequency (Hz) | 80 |
| applied voltage to the auxiliary | |
| electrode | |
| waveform (see, FIG. 26) | rectangular waveform |
| frequency (MHz) | 1 |
| voltage amplitude (V) | 8 & 45 |
| Vp − Vmax (V) | 5 |

* Vp = plasma potential
Vmax = the maximum value of the applied voltage
Vp − Vmax = a potential difference

What is claimed is:

1. A film-forming method for forming a deposited film on a substrate arranged in a substantially enclosed film-forming vessel by means of plasma CVD, said film-forming vessel being provided with a raw material gas introduction means and an exhaustion means, said film-forming method comprising the steps of introducing a raw material gas comprising at least a hydrogen gas and a silicon-containing raw material gas into said film-forming vessel through said raw material gas introduction means, maintaining an inner pressure of said film-forming at a desired value by means of said exhaustion means and introducing a high frequency power into said film-forming vessel through a discharge electrode provided in said film-forming vessel to generate a plasma in a plasma generation region between said substrate and said discharge electrode in said film-forming vessel whereby forming said deposited film on said substrate maintained at a desired temperature, characterized in that the formation of said deposited film on said substrate is performed while applying a periodicity voltage having at least two different waveform components having a different amplitude to an auxiliary electrode arranged at a position in said plasma generation region of said film-forming vessel.

2. The film-forming method according to claim 1, wherein the periodicity voltage has (i) a waveform component having an amplitude capable of generating mainly a radical of a silicon-containing compound and (ii) a waveform component having an amplitude capable of forming mainly a radical of hydrogen.

3. The film-forming method according to claim 1 or 2, wherein the discharge electrode is arranged such that said discharge electrode is opposed to a film-forming surface of the substrate and is situated at a position between the substrate and the discharge electrode.

4. The film-forming method according to claim 1, wherein the auxiliary electrode is arranged to be in parallel to the substrate and perpendicular to a flowing direction of the raw material gas which flows from the raw material introduction means toward the exhaustion means in the film-forming vessel.

5. A film-forming method for forming a deposited film on a substrate arranged in a substantially enclosed film-forming vessel by means of plasma CVD, said film-forming vessel being provided with a raw material gas introduction means and an exhaustion means, said film-forming method comprising the steps of introducing a raw material gas comprising at least a hydrogen gas and a silicon-containing raw material gas into said film-forming vessel through said raw material gas introduction means, maintaining an inner pressure of said film-forming vessel at a desired value by means of said exhaustion means and introducing a high frequency power into said film-forming vessel through a discharge electrode provided in said film-forming vessel to generate a plasma in a plasma generation region between said substrate and said discharge electrode in said film-forming vessel whereby forming said deposited film on said substrate maintained at a desired temperature, characterized in that said substrate is retained in a state of having a floating potential in said film-forming vessel, an auxiliary electrode is provided on a side opposite a film-forming face of said substrate in said film-forming vessel such that said auxiliary electrode is electrically isolated from said substrate, and the formation of said deposited film on said substrate is performed while applying a periodicity voltage having at least two different waveform components having a different amplitude to said auxiliary electrode.

6. The film-forming method according to claim 5, wherein the periodicity voltage has (i) a waveform component having an amplitude capable of generating mainly a radical of a silicon-containing compound and (ii) a waveform component having an amplitude capable of generating mainly a radical of hydrogen.

7. The film-forming method according to claim 5 or 6, wherein the auxiliary electrode is arranged so that even when a conductive deposited is formed on the substrate, said conductive deposited film has a potential capable of being maintained at a floating potential.

8. The film-forming method according to claim 5 or 6, wherein the auxiliary electrode is arranged such that said auxiliary electrode is in parallel to the substrate and is perpendicular to a flowing direction the raw material gas which flows from the raw material gas introduction means toward the exhaustion means in the film-forming vessel.
